(19) United States
(12) Patent Application Publication
(10) Pub. No.: US 2025/0244732 A1
(43) Pub. Date: Jul. 31, 2025

(54) CONTROLLING LI-ION BATTERY SYSTEMS

(71) Applicant: REPSOL, S.A., MADRID (ES)

(72) Inventors: David CASASNOVAS GONZÁLES, MÓSTOLES (ES); David ALLER GIRÁLDEZ, MÓSTOLES (ES); Francisco ALÍA MORENO-ORTÍZ, MÓSTOLES (ES); Manuel CREMADES BUJÁN, CAMPUS VIDA / SANTIAGO DE COMPOSTELA (ES); Juan Nicolás AGUADO, MÓSTOLES (ES); Alfredo BERMÚDEZ DE CASTRO LÓPEZ-VALERA, CAMPUS VIDA / SANTIAGO DE COMPOSTELA (ES); Jerónimo RODRÍGUEZ GARCÍA, CAMPUS VIDA / SANTIAGO DE COMPOSTELA (ES)

(73) Assignee: REPSOL, S.A., MADRID (ES)

(21) Appl. No.: 18/703,286

(22) PCT Filed: Oct. 19, 2021
(86) PCT No.: PCT/EP2021/078981

§ 371 Date: Apr. 19, 2024

(51) Int. Cl. G05B 17/02; H01M 10/0525

(52) U.S. Cl. CPC G05B 17/02; H01M 10/0525

(57) ABSTRACT

Methods are disclosed of controlling operation of a Li-ion battery system. Such methods include obtaining a predicted state of the Li-ion battery system from a reduced order model either with degradation (in first methods) or without degradation (in second methods), and correcting said predicted state by applying a Kalman filter to the predicted state and battery measurements such that an improved predicted state is generated. In second methods, degradation is modelled through degradation model separated or independent from reduced order model without degradation. Li-ion battery system is controlled based on the improved predicted state of the Li-ion battery system. Systems, computing systems and computer programs are also disclosed which are suitable to perform said methods.

This disclosure relates to methods of controlling a Li-ion battery system, and to computer programs, systems and computing systems that are suitable to perform such methods.

### BACKGROUND

The subject matter disclosed herein concerns battery control and more particularly relates to control of Li-ion battery systems. Such Li-ion battery systems are often employed as storage devices for a diversity of systems such as, e.g., portable electronics, electric and hybrid-electric vehicles, houses or apartments or entire apartment buildings, etc. simply because of their high specific energy. Li-ion battery systems are typically characterized by cells containing a negative electrode, a positive electrode, a separator located between the negative and positive electrodes, and corresponding electrolyte. Both electrodes contain active materials where lithium ions may be intercalated.

Controlling a Li-ion battery system refers to control operation of such battery systems to keep the battery under predefined operational limits in terms of, e.g., maximum/minimum voltage, state-of-charge, current, temperature . . . , while suitably responding to power demand requested by user (or consumer device or system). These predefined operational limits are normally specified by the battery manufacturer as a warranty that, if they are respected, the battery will remain useful during its predicted life or even beyond. Basic control systems (e.g. using equivalent circuit models) try to maximize the energy supply while satisfying those operational limits. Advanced control systems (e.g. using physical-based models) are expected to quantify the degradation produced at a given scenario and to try to maximize the energy supply while increasing battery remaining useful life, in contrast with basic control systems. Advanced control systems may thus require more information about the internal state of the battery. These types of prior methods are improvable from both reliability and efficiency perspectives.

The object of the present disclosure is to provide improved methods, computer programs, systems, and computing systems for controlling a Li-ion battery system.

In the present disclosure the terms Li-ion battery system and lithium-ion battery system may be used with the same meaning and the word cell concerns a cell of the Li-ion battery system unless otherwise indicated. In general, same concept may be denominated in different manners whenever they are well known and accepted by skilled peopled in the technical field of operating Li-ion battery systems.

### SUMMARY

In an aspect, methods (also denominated first methods herein) of controlling operation of a Li-ion battery system having configuration specifications are provided. These first methods may include obtaining, based on a porous electrode model including degradation and on the configuration specifications, a reduced order model of the Li-ion battery system having a plurality of selectable versions, and performing an iterative loop. Each iteration of the iterative loop includes determining a predicted state of the Li-ion battery system, determining a present corrected state of the Li-ion battery system, controlling the Li-ion battery system, and keeping or saving involved data.

The determining of the predicted state of the Li-ion battery system is performed by selecting a version of the obtained reduced order model depending on a previous corrected state of the Li-ion battery system from previous iteration of the iterative loop, and by calculating the predicted state based on the selected version of the reduced order model depending on the previous corrected state, a previous corrected current demanded to the Li-ion battery system from previous iteration of the iterative loop, and a present current demanded to the Li-ion battery system. The determining of the present corrected state of the Li-ion battery system is performed by applying a Kalman filter depending on the predicted state and battery measurements from sensors arranged or installed in the Li-ion battery system.

The controlling of the Li-ion battery system is performed based on a present corrected current demanded resulting from correcting (or preserving) the present current demanded depending on the present corrected state. The keeping or saving of involved data is performed by keeping or saving the present corrected state and the present corrected current demanded to be used as the previous corrected state and the previous corrected current demanded, respectively, in subsequent iteration of the iterative loop.

The concept of STATE of a Li-ion battery system is understood herein as any data at least partially representing or denoting an operational state experienced or to be experienced by the Li-ion battery system during its operation. Said state-related data may include any data produced by corresponding version of the (mathematical) reduced order model which is configured to model operation of the Li-ion battery system. As deeply described in other parts of the disclosure, known (mathematical) reduced order model versions aimed at emulating battery behaviour may produce at least a model-state and a model-output. The model-state may be an encoded state of the battery that is being modelled or, in other words, a codification of the operational state undergone or to be undergone by the battery system. The model-output may be seen as an evolved version of the model-state in the sense that the model-output is physically interpretable (versus the non-interpretability of the “encoded” model-state). The model-output may be directly derivable from the model-state through known calculations. It is thus noted that the STATE of the Li-ion battery system and the model-state produced by corresponding version of the reduced order model do not exactly correspond to same concept, but the model-state is included in or is part of the more general or broader STATE of the Li-ion battery system.

Apart from the model-state and the model-output, the STATE of the Li-ion battery system may further include any operational data that is directly derivable from the model-state and/or model-output. Examples of said further operational data may be, e.g., state of charge (SoC) of the battery, temperature of the battery, anode porosity, etc. which may be directly derived from the model-state and/or output through known calculations. In the particular case of anode porosity, it is a parameter or variable at least partially denoting or being caused by degradation of the battery. In the proposed first methods of controlling battery system, degradation and therefore, in some examples, porosity may be modelled along with remaining phenomena occurring within the battery during operation, since reduced order model is obtained based on a porous electrode model including degradation. On the contrary, in second methods of controlling battery system described in other parts of the disclosure, degradation (including porosity in some examples) is determined from a degradation model independently from reduced order model which comes from a porous electrode model without degradation. Therefore, porosity may be part of the STATE of the Li-ion battery system coming from reduced order model only in first methods, but not in second methods.

The concept of STATE of a Li-ion battery system thus corresponds to a dataset including any data outputted by corresponding version of the reduced order model such as, e.g., model-state and model-output and, furthermore, any operational data directly derivable from said model-state and/or model-output such as, e.g., SoC, temperature, porosity (only in first methods), etc.

Predicted STATE corresponds to next STATE expected to be experienced by the Li-ion battery system estimated by selecting a version of the (mathematical) reduced order model depending on previous corrected STATE of the Li-ion battery system, and by calculating the predicted state based on the selected version of the reduced order model depending on the previous corrected STATE, previous corrected current demanded to the Li-ion battery system, and present current demanded to the Li-ion battery system. Previous corrected STATE corresponds to predicted STATE of the Li-ion battery system from previous iteration once corrected (at same previous iteration) based on battery measurements obtained (at same previous iteration) from sensors in/on the Li-ion battery system. Present current demanded corresponds to current that is being demanded presently (at present iteration) to the Li-ion battery system. Previous corrected current demanded corresponds to current demanded (to the Li-ion battery system) from previous iteration once corrected or preserved (at same previous iteration) depending on predicted STATE (determined at same previous iteration) once it has been corrected (at same previous iteration) based on battery measurements obtained (at same previous iteration) from sensors in/on the Li-ion battery system. Previous corrected current demanded may also be denominated current applied at previous iteration, which may be equal to demanded current (preserved current demanded) or less than demanded current (corrected current demanded). In summary, predicted STATE is calculated in present iteration based on predicted STATE from previous iteration once corrected depending on measurements, on current finally applied at previous iteration, and on current presently demanded to the Li-ion battery system.

Reduced order model with plurality of versions may be obtained according to either an on-line building approach or off-line building approach. Off-line building approach means that reduced order model is built off-line (before control of the Li-ion battery system 101) and used on-line (to efficiently control the Li-ion battery system 101). On the contrary, on-line building approach means that reduced order model is built and used on-line (during control of the Li-ion battery system 101).

Experiments performed have proved that first methods permit controlling Li-ion battery systems more reliably and efficiently in comparison to prior methods with same or similar aim. Proposed first methods are feedback-based in the sense that (present) predicted state of the Li-ion battery system is determined depending on previously predicted state once corrected at previous iteration (i.e. predicted state is calculated depending on feedbacked previously predicted state once corrected). It has been empirically verified that such a state prediction based on previous state prediction (i.e. feedback-based prediction) makes first methods more reliable and efficient than prior methods with same or similar aim. Furthermore, the proposed use of “versioned” (mathematical) reduced order model to predict STATE of the Li-ion battery system along with the application of Kalman filter to the mathematically predicted STATE and online measurements to obtain an improved STATE of the battery makes first methods still more reliable. This is conceptually consistent with the fact that mathematical prediction may be potentially subjected to modelling imperfections and control based on online measurements may also be potentially subjected to measurement imperfections. First methods according to present disclosure thus permit compensating such modelling and measurement imperfections to each other, in such a way that optimum equilibrium between the one and other approach is achieved and, therefore, control of the Li-ion battery system is improved.

In a further aspect, methods (also denominated second methods herein) of controlling operation of a Li-ion battery system having configuration specifications are provided. These second methods include obtaining, based on a porous electrode model without degradation and on the configuration specifications, a reduced order model without degradation having a plurality of versions, obtaining a degradation model based on an electrochemical degradation model and on the configuration specifications, and performing an iterative loop. Each iteration of the iterative loop includes determining an estimated degradation, a predicted state and a present corrected state of the Li-ion battery system, controlling the Li-ion battery system, and keeping or saving involved data.

The estimated degradation of the Li-ion battery system is determined based on the degradation model, and on a previous corrected state of the Li-ion battery system from previous iteration of the iterative loop. The predicted state of the Li-ion battery system is determined by selecting a version of the reduced order model without degradation depending on the previous corrected state and the estimated degradation, and by calculating the predicted state based on the selected version of the reduced order model without degradation depending on the previous corrected state, a previous corrected current demanded to the Li-ion battery system from previous iteration of the iterative loop, and a present current demanded to the Li-ion battery system. The present corrected state of the Li-ion battery system is determined by applying a Kalman filter depending on the predicted state and battery measurements from sensors arranged or installed in the Li-ion battery system.

The controlling of the Li-ion battery system is performed based on a present corrected current demanded resulting from correcting (or preserving) the present current demanded depending on the present corrected state. The keeping or saving of involved data is performed by keeping or saving the present corrected state and the present corrected current demanded to be used as the previous corrected state and the previous corrected current demanded, respectively, in subsequent iteration of the iterative loop.

A main difference of second methods with respect to first methods is that, in second methods, reduced order model does not include modelling of degradation but, instead, degradation is modelled independently or separately from reduced order model. In second methods, reduced order model is obtained from a porous electrode model without degradation, and a degradation model is obtained from an electrochemical degradation model. This degradation model is determined independently from the modelling of battery processes or phenomena other than degradation which are modelled through reduced order model without degradation. Despite said difference and adaptations due thereto, same or similar advantages and principles described with respect to first methods are similarly attributable to second methods.

In some examples, same porous electrode model may be used to obtain reduced order model in both first and second methods, with variables exclusively related to degradation defined as calculable parameters in first methods and as non-calculable parameters in second methods. Non-calculable parameter means that there is no equation within the reduced order model to calculate said parameter and, therefore, several reduced order model versions or group of versions may be generated for different values or ranges of the non-calculable parameter. Once said non-calculable parameter is known from estimation of degradation-related data, reduced order model version or group of versions corresponding to said parameter value may be selected to model operation of the Li-ion battery system.

In examples of first and second methods, the obtaining of the reduced order model (with degradation in first methods and without degradation in second methods) may include retrieving the reduced order model from a repository of pre-calculated reduced order models depending on the configuration specifications of the Li-ion battery system. Pre-calculation of such stored reduced order models may be performed in a diversity of manners as described in detail in other parts of the present disclosure. In second methods, the obtaining of degradation model may include retrieving the degradation model from a repository of pre-calculated degradation models depending on the configuration specifications of the Li-ion battery system. Pre-calculation of such stored degradation models may be performed in a diversity of manners as described in detail in other parts of the present disclosure.

In implementations of first and second methods, the obtaining or calculation or pre-calculation of reduced order model (with degradation in first methods and without degradation in second methods) may include determining transfer functions derived from partial differential equations defining the porous electrode model (with degradation in first methods and without degradation in second methods).

In first methods, at least some of such transfer functions may be determined in such a way that degradation rates are modelled at different locations of the Li-ion battery system. In second methods, the degradation model may be determined in such a way that degradation rates are modelled at different locations of the Li-ion battery system. Said different locations of the Li-ion battery system, at which degradation rates are modelled (through or based on transfer functions in first methods and through degradation model in second methods), may include some spatial locations within the anode and/or cathode and/or separator between anode and cathode of the Li-ion battery system.

The modelling of degradation rates through or based on transfer functions in first methods, or through degradation model in second methods may include modelling degradation overpotentials due to lithium stripping or lithium plating or solid-electrolyte interface formation, or any combination thereof. The modelling of degradation overpotentials through or based on transfer functions in first methods, or through degradation model in second methods may include modelling a solid phase potential at anode and/or cathode, or a liquid phase potential at anode and/or cathode and/or at separator of the Li-ion battery system, or any combination thereof.

The modelling of degradation rates through or based on transfer functions in first methods, or through degradation model in second methods may include modelling porosity evolution at anode and/or cathode depending on the modelling of the degradation rates. The modelling of porosity evolution through or based on transfer functions in first methods, or through degradation model in second methods may include modelling mass and charge conservation at anode and/or cathode and/or separator, and modelling lithium flux from anode and/or cathode and/or separator to electrolyte. In particular, the modelling of the lithium flux through or based on transfer functions in first methods, or through degradation model in second methods may include modelling lithium flux due to intercalation and deintercalation, and/or lithium stripping and lithium plating, and/or solid-electrolyte interface formation.

In both first and second methods, the determining of the transfer functions from partial differential equations may include linearizing the partial differential equations around an equilibrium point, and/or applying one or more Laplace transforms to convert the partial differential equations from time to frequency domain.

In examples of first and second methods, the obtaining, calculation or pre-calculation of the reduced order model (with degradation in first methods and without degradation in second methods) may include applying a discrete realization algorithm (DRA), to obtain the reduced order model as a reduced-order discrete-time state-space model (SSM) further depending on predefined operational states or conditions that are known to be experienced by the Li-ion battery system during operation. Such a discrete realization algorithm (DRA) may include a convolution quadrature method based on a Linear Multistep Method. This Linear Multistep Method may be A-stable, preferably stable, at neighbourhood of infinity, strongly zero stable and consistent of order p, with p being greater or equal than one.

In implementations of first and second methods, the reduced-order discrete-time SSM may be defined by SSM-formulas and SSM-matrices intervening in said SSM-formulas. In this case, the predicted state of the Li-ion battery system may be determined by selecting SSM-matrices and solving the SSM-formulas based on the selected SSM-matrices. The selecting of SSM-matrices to solve the SSM-formulas may be performed depending on the previous corrected state of the Li-ion battery system. The solving of the SSM-formulas may be performed depending on the selected SSM-matrices, on the previous corrected state of the Li-ion battery system, and on the previous corrected current demanded and present current demanded to the Li-ion battery system.

In exemplifications of first and second methods, the selecting of the SSM-matrices may include performing a blending method depending on the previous corrected state (and estimated degradation in second methods) of the Li-ion battery system, so as to select some SSM-matrices or others to solve the SSM-formulas. This blending method may include, e.g., verifying whether there exist SSM-matrices corresponding to the previous corrected state (and estimated degradation in second methods), in which case said correspondent SSM-matrices are selected and, otherwise, an interpolation of neighbouring SSM-matrices is performed.

In examples, the performing of the blending method to select some SSM-matrices or others may be performed depending on an average cell temperature included in or derived from the previous corrected state (in both first and second methods), a state-of-charge or SoC included in or derived from the previous corrected state (in both first and second methods), and an average of anode porosity derived from (or included in) the previous corrected state (in first methods) or from the estimated degradation (in second methods).

In first and second methods, the Kalman filter may include an Extended Kalman filter, EKF, or an Unscented Kalman filter, UKF, or a combination thereof. In particular, the Kalman filter may include an Extended Kalman filter including linear equality constraints. Battery measurements (to be processed by Kalman filter) may include a battery voltage, or an average battery temperature, or an average ambient temperature, or a pressure, or any combination thereof. Battery voltage (potential difference between cell ends) may result from determining a difference between solid phase potential at cathode-current collector interface and anode-current collector interface. Average temperature may result from averaging temperatures measured at different regions of the Li-ion battery system. Average ambient temperature/pressure may result from averaging temperatures/pressures measured at different outer regions of the Li-ion battery system.

In examples of first and second methods, the correcting or preserving of the present current demanded may be performed by determining a correction to be applied to the present current demanded. This correction may be determined based on a supply capacity of the Li-ion battery system determined or estimated depending on the present corrected state of the Li-ion battery system. The higher the supply capacity the lower the correction may be, and the lower the supply capacity the higher the correction may be. If such a correction is determined substantially equal to null or zero, the present current demanded may be preserved and, otherwise, the present current demanded may be corrected according to the determined correction.

The correction to be applied to the present current demanded may be determined depending on operational data included in or derivable from the present corrected state. These operational data may include voltage, (average) state of charge, side reaction overpotentials or (average) temperature, or any combination thereof, included in or derivable from the present corrected state.

The correction to be applied to the present current demanded may be determined by, e.g., performing an optimization method to minimize a correction/adjustment function to be applied to the present current demanded. This correction/adjustment function may depend on the present corrected state, in particular, on the aforementioned operational data included in or derivable from the present corrected state. The optimization method may be restricted to one or more constraints that may correspond to operational limits of the Li-ion battery system that may be or may have been (pre-)defined to guarantee safety of the Li-ion battery system. If minimum correction outputted by the optimization method is substantially null or zero, present current demanded may be preserved and, otherwise, present current demanded may be corrected based on minimum correction outputted by the optimization method. Instead of correction/adjustment function minimization, the optimization method may be configured to maximize a multiplier-factor (or correction factor) function to be applied to the present current demanded according to same or similar principles and assumptions as those corresponding to correction/adjustment function minimization. If maximum multiplier factor outputted by the optimization method is, e.g., substantially equal to one, present current demanded may be preserved and, otherwise (maximum multiplier factor less than one), present current demanded may be corrected by multiplying it by the maximum multiplier factor. Conceptually, objectives of correction/adjustment function minimization and multiplier-factor (or correction factor) function maximization may be seen as different versions of same objective, i.e. both approaches perform same function or achieve same objective in different manners or from different perspectives.

The determining of the correction (or multiplier factor) to be applied to the present current demanded may further include performing a low-pass filter between the present current demanded and the previous corrected current demanded. Once the present current demanded has been corrected or preserved accordingly, the Li-ion battery system may be controlled based on control signals aimed at instructing the Li-ion battery system to supply energy according to resulting present corrected current demanded.

In a still further aspect, first computer programs and second computer programs are provided. First computer programs include program instructions for causing a (first) computing system to perform first methods of controlling operation of a Li-ion battery system, such as the ones described in other parts of the disclosure. Second computer programs include program instructions for causing a (second) computing system to perform second methods of controlling operation of a Li-ion battery system, such as the ones described in other parts of the disclosure. Such first and second computer programs may be embodied on a storage medium and/or carried on a carrier signal.

In a yet further aspect, systems (also denominated first systems herein) are provided for controlling operation of a Li-ion battery system having configuration specifications. First systems may include in some implementations a model module and an iterative module including a prediction module, a correction module, a control module, and a saving module. The model module is configured to obtain, based on a porous electrode model including degradation and on the configuration specifications, a reduced order model of the Li-ion battery system having a plurality of selectable versions. The iterative module is configured to perform an iterative loop with each iteration of the iterative loop including performing following functions or steps implemented by modules included in iterative module. The prediction module (in iterative module) is configured to determine a predicted state of the Li-ion battery system by selecting a version of the reduced order model depending on a previous corrected state of the Li-ion battery system from previous iteration of the iterative loop, and by calculating the predicted state based on the selected version of the reduced order model depending on the previous corrected state, a previous corrected current demanded to the Li-ion battery system from previous iteration of the iterative loop, and a present current demanded to the Li-ion battery system. The correction module (in iterative module) is configured to determine a present corrected state of the Li-ion battery system by applying a Kalman filter depending on the predicted state and battery measurements from sensors installed in the Li-ion battery system. The control module (in iterative module) is configured to control the Li-ion battery system based on a present corrected current demanded resulting from correcting (or preserving) the present current demanded depending on the present corrected state. The saving module (in iterative module) is configured to keep or save the present corrected state and the present corrected current demanded to be respectively used as the previous corrected state and the previous corrected current demanded in subsequent iteration of the iterative loop.

In a furthermore aspect, systems (also denominated second systems herein) are provided for controlling operation of a Li-ion battery system having configuration specifications. Second systems include a model module, a degradation module, and an iterative module including an estimation module, a prediction module, a correction module, a control module, and a saving module. The model module is configured to obtain, based on a porous electrode model without degradation and on the configuration specifications, a reduced order model without degradation of the Li-ion battery system having a plurality of selectable versions. The degradation module is configured to obtain a degradation model based on an electrochemical degradation model and on the configuration specifications. The iterative module is configured to perform an iterative loop with each iteration of the iterative loop including performing following functions or steps implemented by modules included in iterative module. The estimation module (in iterative module) is configured to determine an estimated degradation of the Li-ion battery system based on the degradation model, and on a previous corrected state of the Li-ion battery system from previous iteration of the iterative loop. The prediction module (in iterative module) is configured to determine a predicted state of the Li-ion battery system by selecting a version of the reduced order model without degradation depending on the previous corrected state and the estimated degradation, and by calculating the predicted state based on the selected version of the reduced order model without degradation depending on the previous corrected state, a previous corrected current demanded to the Li-ion battery system from previous iteration of the iterative loop, and a present current demanded to the Li-ion battery system. The correction module (in iterative module) is configured to determine a present corrected state of the Li-ion battery system by applying a Kalman filter depending on the predicted state and battery measurements from sensors arranged in the Li-ion battery system. The control module (in iterative module) is configured to control the Li-ion battery system based on a present corrected current demanded resulting from correcting (or preserving) the present current demanded depending on the present corrected state. The saving module (in iterative module) is configured to keep or save the present corrected state and the present corrected current demanded to be respectively used as the previous corrected state and the previous corrected current demanded in subsequent iteration of the iterative loop.

In a still furthermore aspect, first computing systems and second computing systems are provided. First computing systems include a memory and a processor, embodying instructions stored in the memory and executable by the processor, and the instructions including functionalities to execute first methods of controlling operation of a Li-ion battery system, such as the ones described in other parts of the disclosure. Second computing systems include a memory and a processor, embodying instructions stored in the memory and executable by the processor, and the instructions including functionalities to execute second methods of controlling operation of a Li-ion battery system, such as the ones described in other parts of the disclosure.

### BRIEF DESCRIPTION OF THE DRAWINGS

Non-limiting examples of the present disclosure will be described in the following, with reference to the appended drawings, in which:

FIG. 1 shows schematic representations of first systems for controlling a Li-ion battery system, according to examples.

FIG. 2 is a flow chart schematically illustrating first methods of controlling a Li-ion battery system, according to examples.

FIG. 3 shows schematic representations of second systems for controlling a Li-ion battery system, according to examples.

FIG. 4 is a flow chart schematically illustrating second methods of controlling a Li-ion battery system, according to examples.

### DETAILED DESCRIPTION

In these figures the same reference signs may have been used to designate or indicate same or similar elements.

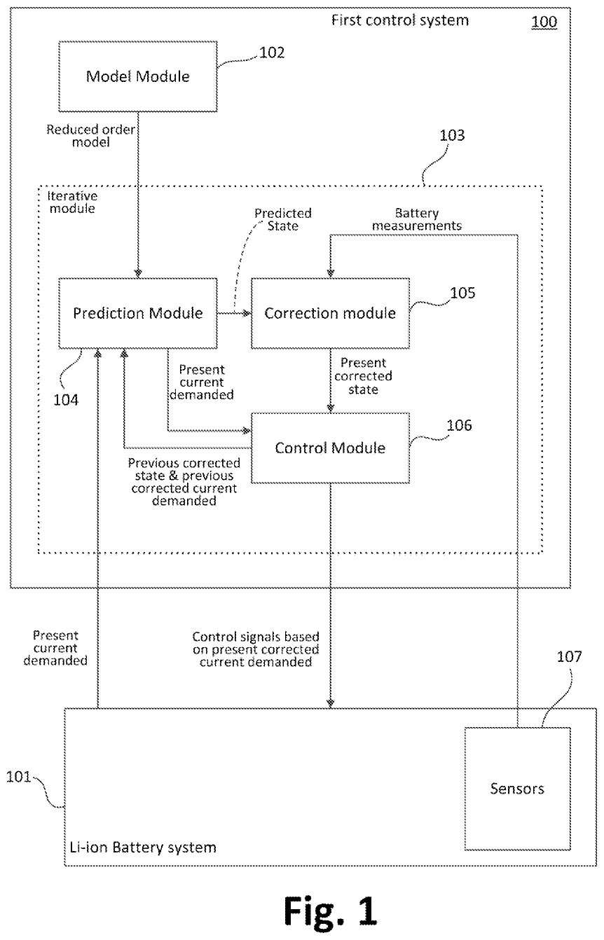

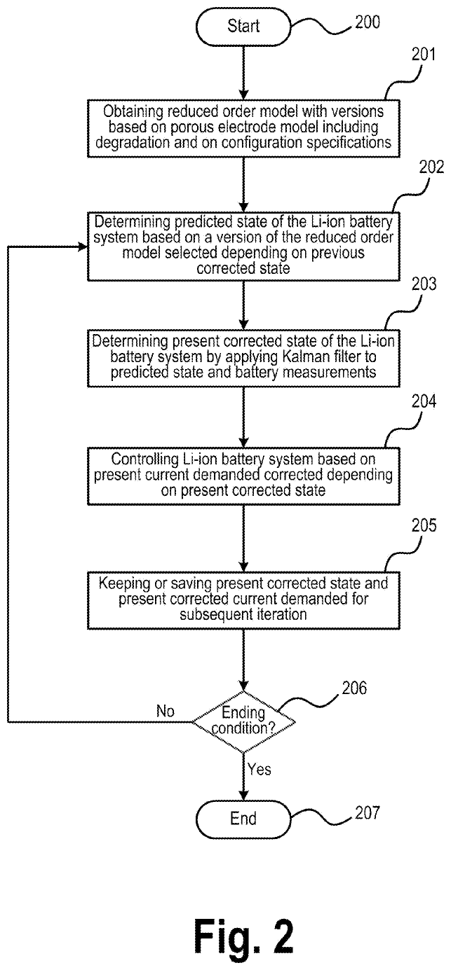

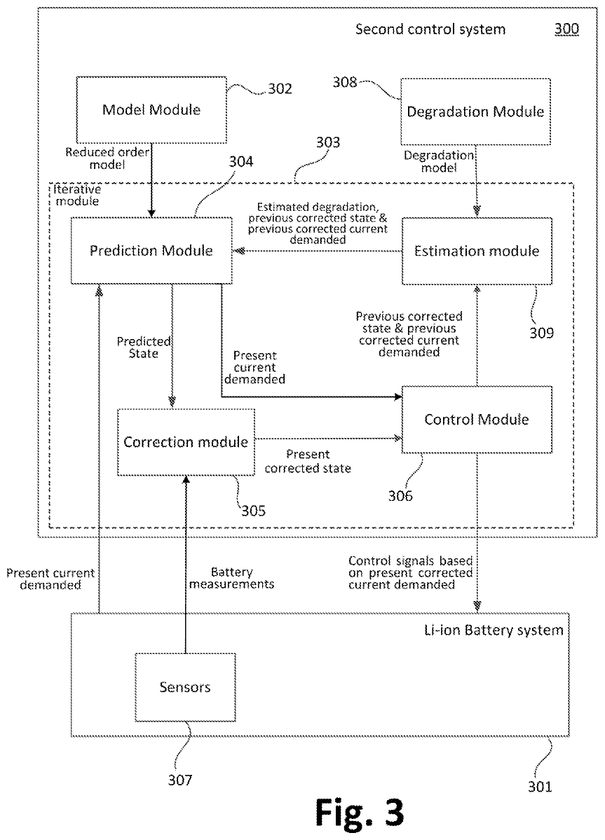

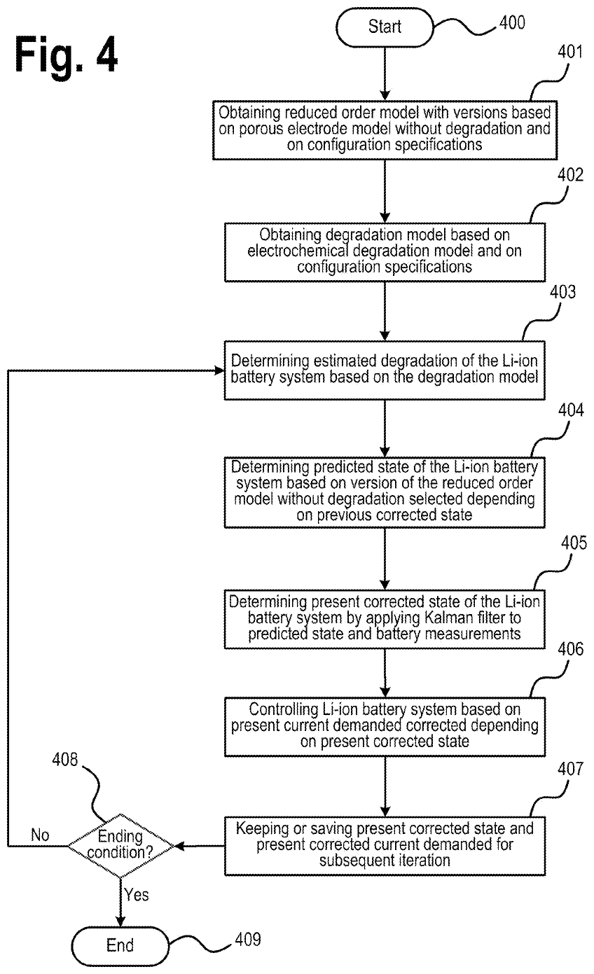

FIG. 1 illustrates first systems 100 for controlling a Li-ion battery system, and FIG. 2 illustrates first methods of controlling a Li-ion battery system that are performable by such first systems 100. First systems 100 may include suitable modules configured to cooperatively perform first methods. FIG. 3 illustrates second systems 300 for controlling a Li-ion battery system, and FIG. 4 illustrates second methods of controlling a Li-ion battery system that are performable by such second systems 300. Second systems 300 may include suitable modules configured to cooperatively perform second methods.

First and second systems 100, 300 disclosed herein may be implemented as respective first and second computing systems having a memory and a processor, embodying instructions (e.g. constituting respective first and second computer programs) stored in the memory and executable by the processor, the instructions having functionalities to execute respective first and second methods of controlling a Li-ion battery system according to the present disclosure. The processor may thus be configured to execute such respective first and second computer programs implementing respective first and second methods of controlling a Li-ion battery system disclosed herein. First and second computing systems 100, 300 may include a repository, such as a conventional hard disk, to store and retrieve data produced and/or required by respective first and second computer programs. Such first and second computer programs may therefore include any piece of software suitable or needed to perform respective first and second methods of controlling a Li-ion battery system.

As used herein, the term “module” may be understood to refer to software, firmware, hardware and/or various combinations thereof. It is noted that the modules are exemplary. The modules may be combined, integrated, separated, and/or duplicated to support various applications. Also, a function described herein as being performed by a particular module may be performed by one or more other modules and/or by one or more other devices instead of or in addition to the function performed by the described particular module.

The modules may be implemented across multiple devices, associated, or linked to respective first and second methods/systems for controlling a Li-ion battery system proposed herein, and/or to other components that may be local or remote to one another. Additionally, the modules may be moved from one device and added to another device, and/or may be included in both devices, associated to respective first and second methods/systems for controlling a Li-ion battery system proposed herein. Any software implementations may be tangibly embodied in one or more storage media, such as e.g. a memory device, a floppy disk, a compact disk (CD), a digital versatile disk (DVD), or other devices that may store computer code.

First and second methods/systems for controlling a Li-ion battery system according to the present disclosure may be implemented by computing resources, electronic resources, or a combination thereof. The computing resources may be a set of instructions (e.g. respective first and second computer programs) and then respective first and second methods/systems for controlling a Li-ion battery system may include a memory and a processor, embodying said set of instructions stored in the memory and executable by the processor. These instructions may include functionality or functionalities to execute respective first and second methods of controlling a Li-ion battery system such as e.g. the ones described in other parts of the disclosure.

In case any of the first and second methods/systems for controlling a Li-ion battery system are implemented only by electronic resources, a controller of the system may be, for example, a CPLD (Complex Programmable Logic Device), an FPGA (Field Programmable Gate Array) or an ASIC (Application-Specific Integrated Circuit).

In case any of the first and second methods/systems for controlling a Li-ion battery system are a combination of electronic and computing resources, the computing resources may be a set of instructions (e.g. respective first and second computer programs) and the electronic resources may be any electronic circuit capable of implementing corresponding method-steps of respective first and second methods of controlling a Li-ion battery system proposed herein, such as the ones described in other parts of the disclosure.

Any of the first and second computer programs may be embodied on a storage medium (for example, a CD-ROM, a DVD, a USB drive, a computer memory or a read-only memory) or carried on a carrier signal (for example, on an electrical or optical carrier signal).

Any of the first and second computer programs may be in the form of source code, object code, a code intermediate source and object code such as in partially compiled form, or in any other form suitable for use in implementing respective first and second methods of controlling a Li-ion battery system according to the present disclosure. The carrier may be any entity or device capable of carrying respective first and second computer programs.

For example, the carrier may include a storage medium, such as a ROM, for example a CD ROM or a semiconductor ROM, or a magnetic recording medium, for example a hard disk. Further, the carrier may be a transmissible carrier such as an electrical or optical signal, which may be conveyed via electrical or optical cable or by radio or other resources.

When any of the first and second computer programs are embodied in a signal that may be conveyed directly by a cable or other device or resources, the carrier may be constituted by such cable or other device or resources. Alternatively, the carrier may be an integrated circuit in which respective first and second computer program are embedded, the integrated circuit being adapted for performing, or for use in the performance of, respective first and second methods of controlling a Li-ion battery system proposed herein.

### Examples of First Systems 100 and Overview Thereof

First systems 100 according to FIG. 1 may include a model module 102 and an iterative module 103. Such an iterative module 103 may include a prediction module 104, a correction module 105, a control module 106, and a saving module (not shown in Figure). Saving module may be configured to save working data determined in present iteration to be used in subsequent iteration, so said module may be included in, e.g., any of the shown modules 104-106 that may know or have access to said working data. One or more sensors 107 may be arranged in/on the Li-ion battery system 101 to sense operational parameters of the Li-ion battery system 101 during its functioning. Sensors 107 may provide measurement values of the Li-ion battery system 101 during its operation.

Modules 104-106 in iterative module 103 of first systems 100 may cooperate to implement an iterative process. In this iterative process, model module 102 may produce a reduced order model with versions mathematically modelling operation of the Li-ion battery system 101, just once at the beginning of the method, in an off-line building approach as described in other parts of the disclosure. Alternatively, model module 102 may produce required reduced order model version at each iteration of the method in an on-line building approach as described in other parts of the disclosure. In the particular examples illustrated, first systems 100 belong to off-line building approach.

Once reduced order model is available, iterative process may be started by e.g. prediction module 104 which may be configured to select a version of the reduced order model (from e.g. model module 102) depending on previous corrected state determined by correction module 105 at previous iteration. Prediction module 104 may then calculate predicted state by calculating the predicted state based on the selected version of the reduced order model depending on previous corrected state, on previous corrected current demanded (i.e. applied current) from previous iteration, and on present current demanded to the Li-ion battery system.

At first iteration, previous corrected state may be a predefined zero state and previous corrected current may be a predefined zero current, simply because there is no previous iteration at which previous corrected state and previous corrected current have been calculated. Version of the reduced order model corresponding to predefined zero previous corrected state may be a predefined initial version of the reduced order model that may have been determined (at e.g. model module 102) depending on predefined initial parameters denoting an initial state and/or condition of the Li-ion battery system 101. For example, if it has been observed empirically that the Li-ion battery system 101 is normally initially charged at a given percentage of SoC (e.g., at 60% of SoC, or at 40% of SoC), said percentage of SoC may be one of such predefined initial parameters. These and other initial parameters denoting most probable initial state and/or condition of the Li-ion battery system 101 may have been considered to predefine such an initial version of the reduced order model.

Once predicted state has been determined, measurements from one or more sensors 107 may be obtained and present corrected state may be generated (by e.g. correction module 105) depending on said measurements from sensors 107 and predicted state determined (by. e.g. prediction module 104) based on selected version of the reduced order model depending on previous predicted state (predefined to zero at first iteration), previous corrected current demanded (also predefined to zero at first iteration), and present current demanded. Accordingly, correction module 105 may generate present corrected state from predicted state in same manner in all iterations (i.e. from first to last iteration).

Once present corrected state has been generated, control module 106 may correct (or preserve) present current demanded (to Li-ion battery 101) depending on present corrected state (from e.g. correction module 105), and output suitable control signals to instruct the Li-ion battery system 101 to supply energy according to said present corrected current demanded (applied current either equal to or less than current demanded). If applied current is equal to current demanded, it means that current demanded has been preserved, and if applied current is less than current demanded, it means that current demanded has been corrected.

As commented in other parts of the disclosure, predicted state may include model-state and model-output produced by reduced order model and, furthermore, any other operational data directly derivable from model-state and/or model-output characterizing next state the Li-ion battery system 101 is estimated to experience. Such other operational data may include, e.g., concentrations at different points of the battery, potentials, voltage, average temperature, state of charge, porosity, etc. which may have physical interpretation useful to generate present corrected state by correction module 105, to control the Li-ion battery system 101 by control module 106, etc.

### Examples of Model Module 102 in First Systems 100

The model module 102 may be configured to obtain (or receive or retrieve) configuration or factory specifications of the Li-ion battery system 101 to be controlled and, in some examples, predefined states or conditions that are known to be experienced by the Li-ion battery system 101 during operation. These predefined states or conditions may depend on the intended application of the Li-ion battery system 101. Configuration specifications may include e.g. cell-level parameters, electrode-related parameters, electrolyte-related parameters and separator-related parameters, i.e. any specification technically characterizing the Li-ion battery system 101 from factory. Predefined states or conditions may include e.g. state of charge (SoC), temperature at different points of the cell, cell porosity (e.g., anode porosity), average temperature of the battery system, etc., i.e. any operational or working state of the Li-ion battery system 101 associated or inherent to the intended application thereof. These specifications and/or states may be inputted manually by competent operator of the Li-ion battery system 101, or may be retrieved by the model module 102 from a repository (e.g. Database) storing such specifications and/or states depending on e.g. a model of the battery, etc. Details on how these inputs may be processed by the model module 102 are provided below.

The model module 102 may be configured to generate a mathematical reduced order model of the Li-ion battery system 101 depending on suitable theoretical principles (porous electrode model including degradation) and on the aforementioned configuration specifications and, in some examples, on pre-known operational states. Different theoretical principles and configuration specifications and, in some examples, pre-known operational states may lead to different mathematical reduced order models modelling operation of the Li-ion battery system 101. The reduced order model (as indicated in FIG. 1) is a mathematical model that permits efficiently modelling operation of the Li-ion battery system 101 and accordingly controlling it. Details on how this output is generated by the model module 102 are provided below.

The model module 102 may be configured to process or compute the abovementioned inputs (theoretical principles, configuration specifications, operational states, etc.) to generate the aforementioned output, i.e. mathematical reduced order model with a plurality of versions. The generation of the versioned mathematical reduced order model may be based on cell dynamics restricted to or influenced by the configuration specifications of the Li-ion battery system 101 and, in some examples, operational states that are known to be experienced by the Li-ion battery system 101 during operation. The versioned mathematical reduced order model (outputted by model module 102) may thus be based on and/or derived from physics-based model(s) of the Li-ion battery restricted to or influenced by known configuration specifications and, in some examples, pre-known operational states of the Li-ion battery system 101.

A diversity of physics-based models is available to model electrochemical reactions occurring within battery cells during operation. The physics-based models may normally be based on or include various partial differential equations and possibly at least one algebraic equation. The partial differential equations that govern the physics-based model arise from fundamental physical principles of charge and mass conservation in solid and liquid phases within Li-ion battery. Examples of physics-based models include e.g., single-particle models and porous-electrode models such as, e.g., the known porous-electrode model described by Doyle, Fuller and Newman.

Single-particle models used as physics-based models may be not able to capture spatially distributed degradation (i.e. to correctly capture degradation scenarios or conditions), which may cause very different results in comparison to models including a spatially distributed degradation model. The model module 102 may start from a porous-electrode model (with suitable restrictions) as theoretical principle or basis to generate the versioned mathematical reduced order model to estimate electrochemical processes taking place within Li-ion battery cell 101. Porous-electrode model may contain or depend on many physical parameters which may include, e.g., cell-level parameters, electrode and/or separator parameters, electrolyte parameters, degradation parameters, etc.

Cell-level parameters may be obtained from configuration specifications and, in some examples, from pre-known operational states, such as e.g. initial temperature, initial state-of-charge (SOC), active area of the cell, mass of the cell, surface area of the cell, volume of the cell, specific heat, heat transfer coefficient, temperature outside the Li-ion battery system 101, etc.

Electrode parameters may be obtained from configuration specifications (and, in some examples, from pre-known operational states), such as e.g. geometry (e.g., thickness), porosity, tortuosity, particle radius, maximum concentrations, thermodynamics, electrical conductivities, thermal conductivities, initial parameters, etc. Thermodynamic parameters may include, e.g., equilibrium potentials, equilibrium potential derivatives with respect to temperature, activation energies, kinetics such as kinetics constants, transport parameters (e.g., diffusion constants), etc. Initial parameters may include, e.g., initial concentrations, initial stoichiometries, etc. at both electrodes. Separator parameters may include geometry (e.g., thickness), porosity, tortuosity, transport parameters (e.g., thermal conductivity), etc.

Electrolyte parameters may be obtained from configuration specifications (and, in some examples, from pre-known operational states), such as e.g. chemical composition of the electrolyte, transport parameters, etc. Transport parameters may include, e.g., diffusivity, ionic conductivity, transport number, activity dependency of the electrolyte, initial concentration of lithium within the electrolyte, etc.

Degradation parameters may be obtained from configuration specifications (and, in some examples, pre-known operational states), such as e.g. initial film thickness, electronic conductivity of the film, ionic conductivity of the film, equilibrium potentials of Solid-Electrolyte Interface (SEI), equilibrium potentials of lithium plating and lithium stripping reactions, exchange current densities of the SEI, plating and stripping reactions, densities lithium plating, stripping and/or SEI, molar masses of lithium plating, stripping and/or SEI, etc.

Using a physics-based model in first systems 100 may imply a high computational complexity, due to the computational cost of resolving partial differential equations. Known physics-based models may be extremely complex to be used directly in first systems 100, as doing so would require solving coupled partial differential equations in real time. First systems 100 may thus use reduced order approximations of such complex physics-based models. Said reduced approximations may be built and used on-line or, alternatively, may be built off-line (before on-line control of the Li-ion battery system 101) and used on-line (to efficiently control the Li-ion battery system 101). First approach corresponding to on-line building and on-line use may be more time consuming (at control time) than second approach based on off-line building and on-line use. In first approach, model module 102 may derive the reduced model and its version required at each time and provide it to corresponding other module (e.g. prediction module 104). In second approach, model module 102 may simply select proper version of a pre-derived reduced model required at each time from, e.g., suitable storage and provide it to corresponding other module (e.g. prediction module 104).

A diversity of strategies is known that may be used to reduce the order and/or the computational complexity of a physics-based model of Li-ion battery system 101. A first strategy may include building physical reduced-order models based on physical assumptions such as, e.g., single-particle models, extended single-particle models, equivalent circuit models, etc. Other strategies may include numerical methods both for space discretization and time integration of the system or building reduced-order models following standard reduced-order modelling approaches such as, e.g., proper generalized decomposition (PGD), dynamic mode decomposition (DMD), state-space model realization techniques, etc.

A reduced-order state-space model may require deriving transfer functions from partial differential equations for variables of interest chosen among variables described by or intervening in full order porous-electrode model. The derivation of the transfer functions described by the porous-electrode model may be achieved by a linearization of the non-linear partial differential equations around an equilibrium point. This derivation may be achieved by deducing one or more transfer functions from one or more partial differential equations that may be part of (or at least partially define) the full order porous-electrode model.

Derivation of the transfer functions may be achieved by a linearization of the porous-electrode model around an equilibrium point and, in some examples, application of Laplace transforms to convert the partial differential equations from time to frequency domain. After deriving the transfer functions, a realization technique that may include discrete realization algorithms, DRA, may be applied. The derivation of transfer functions may imply an easier manner of defining a reduced-order state-space model (SSM) which may be time discrete. A reduced-order discrete-time state-space model (SSM) may be defined according to following SSM-formulas:

$$x ( k + 1 ) = A ( k ) x ( k ) + B ( k ) u ( k ) \qquad Formula 1$$

$$y ( k + 1 ) = C ( k ) x ( k + 1 ) + D ( k ) u ( k + 1 ) \qquad Formula 2$$

wherein:
x(k)∈R^{n×1} may be a state vector of the reduced-order discrete-time SSM, herein so-called also model-state or SSM-state, from previous iteration k, corresponding to previous (corrected) state in FIG. 1, with n corresponding to the order of the model,
u(k)∈R^{m×1} may be an input vector of the reduced-order discrete-time SSM, herein so-called also model-input or SSM-input, from previous iteration k, corresponding to previous corrected current demanded (or current applied at previous iteration k) in FIG. 1, with m corresponding to the number of inputs in the input vector,
x(k+1)∈R^{n×1} may be a state vector of the reduced-order discrete-time SSM, herein so-called also model-state or SSM-state, of present iteration k+1, corresponding to present (corrected) state in FIG. 1,
u(k+1)∈R^{m×1} may be an input vector of the reduced-order discrete-time SSM, herein so-called also model-input or SSM-input, of present iteration k+1, corresponding to present corrected current demanded in FIG. 1,
y(k+1)∈R^{q×1} may be an output vector of the reduced-order discrete-time SSM, herein so-called also model-output or SSM-output, generated at present iteration k+1, corresponding to present (corrected) state in FIG. 1, with q corresponding to the number of outputs in the output vector, and
A(k)∈R^{n×n}, B(k)∈R^{n×m}, C(k)∈R^{q×n}, and D(k)∈R^{q×m} may correspond to matrices of reduced-order discrete-time SSM, herein so-called also model-matrices or SSM-matrices.

First methods of controlling a Li-ion battery system (implemented by first systems 100) may be based on finding or deriving transfer functions of electrochemical variables of interest and then converting these transfer functions into low-order discrete-time state-space approximate models. The approach based on transfer functions of interest may not require spatial discretization, which may be a requirement for simulating full order porous-electrode model based on partial differential equations. Decoupling the approximation from spatial discretization may allow mathematical solutions for any subset of desired internal electrochemical variables, at any selection of internal cell locations of interest. While mathematics and conceptual complexity behind finding or deriving transfer functions may be high, the final computational complexity of the model may be highly reduced. The development of transfer functions from nonlinear partial differential equations model of a Li-ion battery system 101 may be based on assumptions such as, e.g., locally linear behavior (since actual equations may be nonlinear, they may be linearized using, e.g., Taylor series), electrolyte potential defined as a function predominantly depending on reaction flux density, etc.

The locally linear behavior assumption may be suitable to create transfer functions since transfer functions exist only for linear systems. The electrolyte potential assumption may imply that the effect of electrolyte concentration on the electrolyte potential may be negligible. The electrolyte potential assumption may simplify the process for finding transfer functions of cell electrochemical variables, albeit any approximation may acceptably decrease accuracy. The electrolyte potential assumption may be most valid when the cell is being operated with rapidly changing input currents, such as for a hybrid electric-vehicle type applications, where no concentration gradient could develop in the electrolyte. Hence, the electrolyte potential assumption may fail in cases in which the cell is operated with constant-current inputs, i.e., plug-in charging an electric vehicle. However, this possible failing of the electrolyte potential assumption is completely assumable since negative influence thereof on modelling results may be negligible or almost negligible.

Cell dynamics of the porous-electrode model may be described by four continuum-scale partial-differential equations and a coupling algebraic closure term. The four partial differential equations may describe mass and charge conservation in the solid and the electrolyte; the closure term may describe lithium flux from the solid to the electrolyte.

The partial differential equations describing the Li-ion transport within the electrolyte may have following form

$${ϵ}_{e}^{n} ( x , t ) \frac{\partial {c}_{e}^{n}}{\partial t} ( x , t ) - \frac{1}{{( {L}^{n} )}^{2}} \frac{\partial }{\partial x} ( {D}_{e , eff}^{n} ( x , t ) \frac{\partial {c}_{e}^{n}}{\partial x} ( x , t ) ) = ( 1 - {t}_{+} ) {a}_{s}^{n} {j}_{tot}^{n} ( x , t ) , x ∈ ( 0 , 1 ) , t > 0 \qquad Formula 3$$

$${ϵ}_{e}^{s} ( x , t ) \frac{\partial {c}_{e}^{s}}{\partial t} ( x , t ) - \frac{1}{{( {L}^{s} )}^{2}} \frac{\partial }{\partial x} ( {D}_{e , eff}^{s} ( x , t ) \frac{\partial {c}_{e}^{s}}{\partial x} ( x , t ) ) = 0 , x ∈ ( 0 , 1 ) , t > 0 \qquad Formula 4$$

$${ϵ}_{e}^{p} ( x , t ) \frac{\partial {c}_{e}^{p}}{\partial t} ( x , t ) - \frac{1}{{( {L}^{p} )}^{2}} \frac{\partial }{\partial x} ( {D}_{e , eff}^{p} ( x , t ) \frac{\partial {c}_{e}^{p}}{\partial x} ( x , t ) ) = ( 1 - {t}_{+} ) {a}_{s}^{p} {j}_{tot}^{p} ( x , t ) , x ∈ ( 0 , 1 ) , t > 0 \qquad Formula 5$$

wherein ∈ₑ^{r} may denote porosity in the electrolyte, cₑ^{r} may denote Li-ion concentration within electrolyte, r∈{n, s, p} is negative electrode, separator, and positive electrode regions, respectively; D_{e,eff}^{r} may denote an effective diffusion coefficient of lithium transport in the electrolyte; L^{r} may denote a thickness of the cell (Lⁿ thickness of negative electrode, L^{s} thickness of separator, L^{p} thickness of positive electrode); aₛ^{r} may denote a surface area of active material particles (e.g., aₛⁿ for the negative electrode, ay for the positive electrode); and jₜₒₜ^{r}(x, t) may denote a total lithium flux due to electrochemical reactions. jₜₒₜⁿ(x, t) may include e.g., following reactions at negative electrode: intercalation/deintercalation, lithium stripping/lithium plating and solid-electrolyte interface formation. The concentrations may be expressed, e.g., in mol/m³.

This equation defined by formulas 3-5 may be supplemented with no-flux boundary conditions such as, e.g., following ones:

$$\begin{matrix}\frac{\partial {c}_{e}^{n}}{\partial x} ( 0 , t ) = 0 , & t > 0\end{matrix} \qquad Formula 6$$

$$\begin{matrix}\frac{\partial {c}_{e}^{p}}{\partial x} ( 1 , t ) = 0 , & t > 0\end{matrix} \qquad Formula 7$$

transmission conditions such as, e.g., following ones:

$$\begin{matrix}{c}_{e}^{n} ( 1 , t ) = {c}_{e}^{s} ( 0 , t ) , & t > 0\end{matrix} \qquad Formula 8$$

$$\begin{matrix}{c}_{e}^{s} ( 1 , t ) = {c}_{e}^{p} ( 0 , t ) , & t > 0\end{matrix} \qquad Formula 9$$

$$\begin{matrix}\frac{{D}_{e , eff}^{n} ( 1 , t )}{{L}^{n}} \frac{\partial {c}_{e}^{n}}{\partial x} ( 1 , t ) = \frac{{D}_{e , eff}^{s} ( 0 , t )}{{L}^{s}} \frac{\partial {c}_{e}^{s}}{\partial x} ( 0 , t ) , & t > 0\end{matrix} \qquad Formula 10$$

$$\begin{matrix}\frac{{D}_{e , eff}^{s} ( 1 , t )}{{L}^{s}} \frac{\partial {c}_{e}^{s}}{\partial x} ( 1 , t ) = \frac{{D}_{e , eff}^{p} ( 0 , t )}{{L}^{p}} \frac{\partial {c}_{e}^{p}}{\partial x} ( 0 , t ) , & t > 0\end{matrix} \qquad Formula 11$$

and initial conditions such as, e.g., following ones:

$$\begin{matrix}{c}_{e}^{n} ( x , 0 ) = {c}_{e , ini}^{n} ( x ) , & x ∈ ( 0 , 1 )\end{matrix} \qquad Formula 12$$

$$\begin{matrix}{c}_{e}^{s} ( x , 0 ) = {c}_{e , ini}^{s} ( x ) , & x ∈ ( 0 , 1 )\end{matrix} \qquad Formula 13$$

$$\begin{matrix}{c}_{e}^{p} ( x , 0 ) = {c}_{e , ini}^{p} ( x ) , & x ∈ ( 0 , 1 )\end{matrix} \qquad Formula 14$$

Derivation of associated transfer functions may be based on assuming that porosity is constant per region in both space and time. Such assumption may allow linearizing the partial differential equations around an equilibrium point and applying Laplace transform to arrive at following homogeneous differential equation:

$$\begin{matrix}\frac{{\partial }^{4}}{\partial {z}^{4}} \frac{( x , s )}{{I}_{a p p} ( s )} - {τ}_{1}^{n} ( s ) \frac{{\partial }^{2}}{\partial {z}^{2}} \frac{( x , s )}{{I}_{a p p} ( s )} + {τ}_{2}^{n} ( s ) \frac{( x , s )}{{I}_{a p p} ( s )} = 0 , \\ x ∈ ( 0 , 1 ) , s ∈ ℂ\end{matrix} \qquad Formula 15$$

$$\begin{matrix}\frac{{\partial }^{2}}{\partial {z}^{2}} \frac{( x , s )}{{I}_{a p p} ( s )} + {τ}_{1}^{s} ( s ) \frac{( x , s )}{{I}_{app} ( s )} = 0 , & x ∈ ( 0 , 1 ) , s ∈ ℂ\end{matrix} \qquad Formula 16$$

$$\begin{matrix}\frac{{\partial }^{4}}{\partial {z}^{4}} \frac{( x , s )}{{I}_{a p p} ( s )} - {τ}_{1}^{p} ( s ) \frac{{\partial }^{2}}{\partial {z}^{2}} \frac{( x , s )}{{I}_{a p p} ( s )} + {τ}_{2}^{p} ( s ) \frac{( x , s )}{{I}_{a p p} ( s )} = 0 , \\ x ∈ ( 0 , 1 ) , s ∈ ℂ\end{matrix} \qquad Formula 17$$

wherein [symbol] (x, s) may denote the Laplace transform of Li-ion concentration in the electrolyte and r∈{n, s, p} is the negative electrode, separator, and positive electrode regions, respectively.

A solution to the previous homogeneous differential equation defined by formulas 15-17 may be expressed in following form:

$$\frac{( x , s )}{{I}_{a p p} ( s )} = {c}_{1}^{n} {e}^{{Λ}_{1}^{n} ( s ) x} + {c}_{2}^{n} {e}^{- {Λ}_{1}^{n} ( s ) x} + {c}_{3}^{n} {e}^{{Λ}_{2}^{n} ( s ) x} + {c}_{4}^{n} {e}^{- {Λ}_{2}^{n} ( s ) x} , x ∈ ( 0 , 1 ) , s ∈ ℂ \qquad Formula 18$$

$$\begin{matrix}\frac{( x , s )}{{I}_{app} ( s )} = {c}_{1}^{s} {e}^{{Λ}_{1}^{s} ( s ) x} + {c}_{2}^{s} {e}^{- {Λ}_{1}^{s} ( s ) x} , & x ∈ ( 0 , 1 ) , s ∈ ℂ\end{matrix} \qquad Formula 19$$

$$\begin{matrix}\frac{( x ,}{{I}_{app} ( s )} = {c}_{1}^{p} {e}^{{Λ}_{1}^{p} ( s ) x} + {c}_{2}^{p} {e}^{- {Λ}_{1}^{p} ( s ) x} + {c}_{3}^{p} {e}^{{Λ}_{2}^{p} ( s ) x} + {c}_{4}^{p} {e}^{- {Λ}_{2}^{p} ( s ) x} , \\ x ∈ ( 0 , 1 ) , s ∈ ℂ\end{matrix} \qquad Formula 20$$

wherein cₑⁿ may denote the Laplace transform of the Li-ion concentration in the electrolyte at the negative electrode, Cₑ^{p} may be the Laplace transform of the Li-ion concentration in the electrolyte at the positive electrode, Cₑ^{s} may be the Laplace transform of the Li-ion concentration in the electrolyte at the separator, and Iₐₚₚ may be Laplace transform of the current circulating in the Li-ion battery system 101. The dependency from x may allow computing the Li-ion concentration in the electrolyte at any desired point within the cell. The coefficients cᵢⁿ, cᵢ^{p}, i=1, . . . , 4, and c₁^{s}, cₛ² may be used to derive the other transfer functions characterizing the porous-electrode model, which may include transfer functions for the solid phase potential ϕₛ at the anode and/or at the cathode, and the liquid phase potential ϕₑ at the anode, at the cathode and/or at the separator between the electrodes. The coefficient Λ₁^{r}(s) may denote a first coefficient from solving the homogeneous fourth order partial differential equation for each of the negative electrode, separator, and positive electrode regions, according to the definition of r∈{n, s, p}. Similarly, the coefficient Λ₂^{r}(s) may denote a second coefficient from solving the homogeneous fourth order partial differential equation for each of the negative electrode, separator, and positive electrode regions. Calculating degradation rates at different locations of the cell of the Li-ion battery system may improve the accuracy of modelling degradation as the degradation overpotentials may take different values within the cell thickness. The degradation overpotentials for the lithium stripping, lithium plating and solid-electrolyte interface formation may be modelled through following formulas respectively:

$${η}_{lst} ( x , t ) = {ϕ}_{s}^{n} ( x , t ) - {ϕ}_{e}^{n} ( x , t ) - {U}_{lst} \qquad Formula 21$$

$${η}_{l p l} ( x , t ) = {ϕ}_{s}^{n} ( x , t ) - {ϕ}_{e}^{n} ( x , t ) - {U}_{l p l} \qquad Formula 22$$

$${η}_{s e i} ( x , t ) = {ϕ}_{s}^{n} ( x , t ) - {ϕ}_{e}^{n} ( x , t ) - {U}_{s e i} - {R}_{e , film} \frac{{j}_{tot}^{n} ( x , t )}{{a}_{s}^{n}} \qquad Formula 23$$

wherein ηₗₛₜ may denote an overpotential for lithium stripping, ηₗₚₗ an overpotential for lithium plating, and ηₛₑᵢ an overpotential for solid-electrolyte interface formation, Uₗₛₜ may denote the lithium stripping at a first equilibrium potential, Uₛₑᵢ the SEI at a second equilibrium potential and Uₗₚₗ the lithium plating at a third equilibrium potential. The term Uₗₚₗ may be defined equivalently as the potential under which lithium plating may occur or may start to occur. The potentials ϕₛ and ϕₑ, respectively in solid and liquid phases, may be computed from transfer functions derived from the porous electrode model.

In examples, state-space model (SSM) may include a thermal model. The partial differential equation (of the porous-electrode model) for temperature evolution may require initial and boundary conditions and may have following form:

$$ρ {c}_{p} \frac{\partial T}{\partial t} ( x , t ) = ∇ \cdot ( λ ∇ T ( x , t ) ) + q ( x , t ) \qquad Formula 24$$

wherein ρ is the density of the cell, cₚ is the specific heat of the cell, λ is the thermal conductivity of the cell, ∇T(x,t) is the gradient of the temperature, and q(x,t) denotes the heat source.

The partial differential equation defined by formula 24 may have convective boundary conditions such as, e.g., following ones:

$$- λ \frac{\partial T}{\partial x} ( x , t ) {\vert}_{x = 0} = h ( {T}_{∞} - T ( 0 , t ) ) \qquad Formula 25$$

$$+ λ \frac{\partial T}{\partial x} ( x , t ) {\vert}_{x = L} = h ( {T}_{∞} - T ( L , t ) ) \qquad Formula 26$$

from which a discrete-time equation for average cell temperature evolution may be derived, wherein h may denote the heat exchange coefficient with the exterior, and T_{∞} the external temperature (temperature at the exterior, e.g., outside the cell).

The heat source term may consider various factors such as effects in anode, in cathode and in separator between electrodes (anode and cathode). Examples of effects considered may include Joule heating effect at solid and liquid phases, reversable heating generation and irreversible heating generation.

In implementations of the model module 102, SSM-formulas 1 and 2 previously described may be adapted to fit in particular manners of implementing reduced-order state-space model (SSM) according to present disclosure. Said adapted SSM-formulas may be expressed in following manner

$$x ( k + 1 ) = A ( k ) \overline{x} ( k ) + B ( k ) \overline{u} ( k ) \qquad Formula 1 a$$

$$y ( k + 1 ) = C ( k ) x ( k + 1 ) + D ( k ) u ( k + 1 ) \qquad Formula 2 a$$

wherein:
x̅(k) may correspond to corrected x(k) of formula 1, i.e. previous corrected state of the Li-ion battery system 101 from e.g. control module 106 at present iteration, and generated at previous iteration by e.g. correction module 105,
ū(k) may correspond to corrected u(k) of formula 1, i.e. previous corrected current demanded to the Li-ion battery system 101 from e.g. control module 106 at present iteration, and generated at previous iteration by e.g. control module 106, and
remaining data intervening in formulas 1a and 2a may be same or similar as those of formulas 1 and 2, respectively.

In examples, matrices A(k), B(k), and C(k) may be non-null in corresponding state space representation and matrix D(k) may be null (in more reduced models) or non-null (in less reduced models). The model module 102 may implement a discrete-time state-space model derived from a full order porous-electrode model and application of a discrete time realization algorithm (DRA). The discrete-time realization algorithm (DRA) may convert a continuous function (from full order porous-electrode model) into a discrete-time unit pulse response, and then a Ho-Kalman or a realization algorithm based in a subspace of eigenvectors and eigenvalues may be used.

The discrete-order realization algorithm DRA may include, e.g., performing an inverse fast Fourier transform (iFFT) at a sampling rate capable to achieve a continuous-time unit pulse response of one or more internal variables, and integrating the continuous-time unit pulse response to obtain a continuous time-step response of one or more internal variables. The sampling of a continuous time-step response may allow defining a discrete-time unit pulse response of one or more of the internal variables, using such discrete-time unit pulse response with the Ho-Kalman algorithm, which may represent a realization algorithm providing construction of minimal state space models of linear time-invariant systems by solving the problem using the so-called Markov parameters expansion.

The accuracy and stability of a DRA may highly depend on some of the hyper-parameters thereof. A system (e.g. Li-ion battery system 101) may be represented by a given transfer function and time step for the model, according to which the associated Markov parameters may be defined by the response of the system to the unit pulse, which conventionally may be unitary for intervals included between 0 and the time step and null elsewhere. By considering the continuous-time unit pulse response, related to the transfer function derived by a Laplace inversion transformation within a suitable contour, the Markov parameters may be computed by convolution between the transfer function and the unit pulse. In examples of first systems 100 for controlling a Li-ion battery system 101, the model module 102 may implement a discrete-realization algorithm comprising a Ho-Kalman realization algorithm and an approximation of Markov parameters calculated by a convolution quadrature (CQ) based on Linear Multistep Methods (LMM), which may guarantee that the transfer function is exponentially stable.

In first systems 100 for controlling a Li-ion battery system 101, the model module 102 may implement a discrete-realization algorithm based on LMM, which may guarantee A-stability, stability at the neighbourhood of infinity, zero stability, strongly zero stability or any combination thereof.

There exist several approaches to implement an LMM. As example, an LMM may be characterized by one step, second order and A-stable method with coefficients defined by the often-called trapezoidal rule based on characteristic polynomials, wherein the approximation for the convolution quadrature coefficients may be associated to Tustin's formula. Such an approach may imply that the coefficients may be expressed in the imaginary axis, and consequently, the transfer function may need to be evaluated for complex numbers that are far from the origin of axis. Such an approach may suffer (acceptable) numerical issues derived from overflow or underflow. A proper evaluation of the transfer function may need an alternative expression for the transfer function for large complex numbers on the imaginary axis.

In examples of first systems 100 for controlling a Li-ion battery system 101, the model module 102 may implement a discrete-realization algorithm based on an LMM that may be characterized by a one step, first order, A-stable and stable at the neighbourhood of an infinity method, e.g., the so-called implicit Euler method, with coefficients defined through characteristic polynomials, wherein the approximation for the convolution quadrature coefficients may be associated to Post's formula. Such an approach may overcome a limitation over prior implementations and circumvent the issues raised by coefficients of LMM defined through the Tustin's formula as the selection of the radius may be tuned to allow characteristic polynomials mapping a circumference included in the positive real part of the complex half-plane. Experiments showed said surprising or unexpected effect. In other examples of first systems 100, the radius may be set equal to one.

In examples, the model module 102 may implement a discrete-realization algorithm based on an LMM that may be characterized by a two-step, second order, A-stable and stable at the neighbourhood of the infinity method with coefficients associated to characteristic polynomials in such a way that a so-called Backward Differentiation Formula of order 2 is defined. Such an approach may overcome a limitation over prior implementations and circumvent issues raised by coefficients of LMM defined through the Tustin's formula as the characteristic polynomials may map a circumference centred at the origin into a closed bounded curve in the positive real part complex half-plane. Experiments showed said surprising or unexpected effect.

In present section about examples of model module 102, particular manners of and fundamentals for deriving reduced order models have been described, but skilled people will appreciate that other manners of doing so may be similarly practicable and/or implementable. No deep (known) details about modelling and reducing full order model have been provided in order not to unnecessarily obscure the present description and developments. Mechanistic description of models and their transition towards reduced order model have been provided, from which skilled people should be able to implement examples of first systems 100 according to present disclosure.

### Examples of Prediction Module 104 in First Systems 100

The prediction module 104 may be configured to receive or obtain from e.g. model module 102 the reduced order (mathematical) model (e.g. reduced order SSM along with precalculated SSM-matrices intervening in the reduced order SSM, and further input data). In examples, these further input data may include previous corrected state, previous corrected current demanded to the Li-ion battery system 101, present current demanded to the Li-ion battery system, etc.

Previous corrected state may correspond to predicted state calculated at previous iteration (by e.g. prediction module 104) once corrected at same previous iteration (by e.g. correction module 105). Said predicted state calculated and corrected at previous iteration may correspond, in terms of FIG. 1, to present corrected state which may have been saved at same previous iteration (by e.g. saving module) to be used as previous corrected state at present iteration. Since, at previous iteration, present corrected state may have passed e.g. from correction module 105 to control module 106, at present iteration, previous corrected state may pass e.g. from control module 106 to prediction module 104.

Previous corrected current demanded may correspond to current demanded at previous iteration to the Li-ion battery system 101 once corrected or preserved at same previous iteration (by e.g. control module 106). Said current demanded and corrected at previous iteration may correspond, in terms of FIG. 1, to present corrected current demanded which may have been saved at same previous iteration (by e.g. saving module) to be used as previous corrected current demanded at present iteration. Since, at previous iteration, present corrected current demanded has been processed by e.g. control module 106, at present iteration, previous corrected current demanded may pass e.g. from control module 106 to prediction module 104.

Present current demanded (at present iteration) to the Li-ion battery system 101 may come e.g. from sensors 107 arranged or installed in/on/at the Li-ion battery system 101, or from pre-existing module in the Li-ion battery system 101 that may know or have access to current presently demanded.

Apart from receiving or obtaining aforementioned input data, prediction module 104 may be further configured to generate and output predicted state of the Li-ion battery system 101 (at present iteration), to output present current demanded (also at present iteration), etc. Since present current demanded may be received or obtained by prediction module 104 from Li-ion battery system 101, prediction module 104 may also output present current demanded to pass it to control module 106.

As described in other parts of the description, predicted state may correspond to that state which is estimated to be experienced by the Li-ion battery system, said state including diverse data representing or denoting such a state to be experienced by the Li-ion battery system 101. Said diverse data may include SSM-state, SSM-output, other data directly derivable from SSM-state and/or SSM-output, such as e.g. average temperature, average porosity, average SoC, etc. corresponding to said SSM-state and/or SSM-output.

To generate predicted state, prediction module 104 may first select those SSM-matrices A(k), B(k), C(k), D(k) that are representative of or correspond to previous corrected state (denoted by e.g. previous corrected average temperature, average SoC, average porosity, etc.) outputted at previous iteration by e.g. correction module 105, processed at previous iteration by e.g. control module 106 to control the Li-ion battery system 101, etc. This selection of SSM-matrices (i.e. version of the reduced order model) may be performed further depending on other data included in previous corrected state. In examples, a blending method or process may be performed to select corresponding SSM-matrices A(k), B(k), C(k), D(k) or version of the reduced order model corresponding to previous corrected state.

Such a model blending may depend on e.g. previous corrected average temperature, average SoC, average porosity, etc. to select those SSM-matrices (or version of the reduced order model) corresponding to previous corrected state (i.e. combination of average temperature, average SoC, average porosity, etc. defining or representing previous corrected state). Model blending method may include interpolation of SSM-matrices in case that previous corrected state (e.g. particular combination of previous corrected average temperature, average SoC, average porosity, etc.) does not have particular predefined SSM-matrices (or version of the reduced order model) associated thereto. In this scenario, an interpolation of predefined SSM-matrices that are closest to represent or correspond to the previous corrected state may be performed to obtain calculated SSM-matrices accurately representing previous corrected state.

Prediction module 104 may be configured to transform one or more of the selected or interpolation-based generated characteristic matrices (or SSM-matrices) of the state-space model into a standard form by applying a first transformation, wherein characteristic matrix may be multiplicated by a first diagonal matrix formed by eigenvalues thereof and the reciprocal of the first diagonal matrix. Prediction module 104 may be further configured to transform one or more of the selected or interpolation-based generated characteristic matrices (or SSM-matrices) of the state-space model into a standard form by applying a second transformation, wherein characteristic matrix may be multiplicated by a second diagonal matrix of the transpose thereof and the reciprocal of the second diagonal matrix. These first and second transformations may allow defining a standard state-space system more suitable to implement the blending process that, e.g., may need less memory storage requirements.

Once appropriate SSM-matrices A(k), B(k), C(k), D(k) have been selected or interpolation-based generated, prediction module 104 may resolve SSM-formulas 1a and 2a described in other parts of the description (i.e. compute selected version of the reduced order model), depending on selected or interpolation-based generated SSM-matrices A(k), B(k), C(k), D(k) and other data. These other data may include, e.g., previous corrected SSM-state x(k), previous corrected current demanded to the Li-ion battery system ū(k), and present current demanded u(k+1).

Resolution of equations 1a and 2a may then produce predicted state which may include SSM-state x(k+1), SSM-output y(k+1), and possibly other operational data directly derivable from SSM-state and/or SSM-output, such as e.g. (average) temperature, porosity, SoC, etc. corresponding to said SSM-state and/or SSM-output. Further operational data that may represent and, therefore, be included in predicted state may include, e.g., concentrations at different points of the battery, potentials, voltage, outer temperature, etc. which may be physically interpretable and, hence, may also be useful to correct predicted state (by e.g. correction module 105), to control Li-ion battery system 101 (by e.g. control module 106), etc. Physical interpretation of such operational data may be determined by performing, at e.g. prediction module 104 and/or correction module 105, non-linear corrections on said operational data.

In present section about examples of prediction module 104, particular manners of and fundamentals for using reduced order model (from e.g. model module 102) have been described, but skilled people will appreciate that other manners of doing so may be similarly practicable and/or implementable. No deep (known) details about using reduced order model for state prediction have been provided in order not to unnecessarily obscure the present description and developments, from which skilled people should be able to implement examples of first systems 100 according to present disclosure.

### Examples of Correction Module 105 in First Systems 100

Correction module 105 may be configured to receive or obtain (at present iteration) predicted state determined by e.g. prediction module 104 and battery measurements from sensors 107 arranged in the Li-ion battery system 101 configured to sense or measure parameters of the Li-ion battery system 101.

The one or more sensors 107 may be configured to derive or infer battery state information or measurements from sensor signals received from battery system 101. The one or more sensors 107 may be internal or external to the Li-ion battery system 101 and may measure battery parameters such as, e.g., temperature, voltage, current, etc. at the Li-ion battery system 101. For instance, a thermocouple may be arranged at exterior of the battery system 101 in, e.g., a single location to measure temperature at said external location. Alternatively, a plurality of thermocouples may be arranged at the Li-ion battery system 101 to measure temperature at several locations of the Li-ion battery system 101 to improve the accuracy of the measurements. The one or more sensors 107 may derive battery state information or measurements in terms of parameters such as, e.g., cell voltage, cell current, cell resistance, cell capacity, cell impedance, cell lifetime, cell power capability, temperature, etc. Temperature may be measured at different locations in/on the battery system 101. Further examples of sensors 107 that may be arranged in/on/at the Li-ion battery system 101 may include pressure sensors and/or acoustic sensors. The one or more sensors 107 may be configured to derive battery state information or measurements with a sample rate suitable for obtaining a precise model thereof. This sample rate may be low enough to not exceed the consumption required to work in reasonable times according to the application of the Li-ion battery system 101.

The correction module 105 may be further configured to output present corrected state (which will be used as previous corrected state in subsequent iteration) calculated from the received predicted state and battery measurements at present iteration.

Once received, said data (from sensors 107 and prediction module 104) may be used by correction module 105 to correct the predicted state depending on the measurements received from the one or more sensors 107. The correction module 105 may implement a Kalman filter, an extended Kalman filter or an Unscented Kalman filter to perform said correction and accordingly output present corrected state (previous corrected state in subsequent iteration).

As described before, correction module 105 may include a Kalman filter for linear discrete models. Since Kalman filter and associated formulas are well known in the involved technical field, no detailed description in this respect is provided. Kalman filter may be applied to the following formulas which are same or similar as formulas 1a and 2a but with noise in state and measurement included.

$$\begin{matrix}x ( k + 1 ) = A ( k ) \overline{x} ( k ) + B ( k ) \overline{u} ( k ) + w ( k + 1 ) \\ y ( k + 1 ) = C ( k ) x ( k + 1 ) + D ( k ) u ( k + 1 ) + v ( k + 1 ) \\ k = 0 , … N\end{matrix} \qquad Formula 27$$

$$\overline{x} ( 0 ) = {x}_{0} + ζ \qquad Formula 28$$

wherein w(k) may correspond to process noise for values of k between 1 and N, which may be a normally distributed random vector of dimension n with average 0 and variance matrix Q(k); in usual notation w(k) may be N (0, Q(k)); v(k) may correspond to measurement noise for values of k between 1 and N, which may be a normally distributed random vector of dimension n with average 0 and variance matrix R(k); in usual notation w(k) may be N (0, R(k)); and ζ may correspond to initial perturbation with average 0 and variance matrix P₀, that may be stated by, e.g., notation N (0, P₀).

Correction module 105 may implement an extended Kalman filter which may have present predicted state (vector) and present measurements as inputs, and present corrected state (vector) as output. The extended Kalman filter may be conceptually seen as based on calculating an average of the predicted state vector and of the measurements using a weighted averaging. The weights may be calculated based on, e.g., covariance (a measure of estimated uncertainty of the prediction of the system's state) represented by covariance matrices. This way, proper weights may be determined such that values with better (i.e., smaller) estimated uncertainty may be considered more reliable. As commented before, Kalman filter formulas are not provided herein because they and their application are very well known. Kalman filter may thus have as further inputs covariance matrices and filter's gain, both from previous iteration. In particular, covariance matrices may include first matrix associated with uncertainty about state, second matrix associated with uncertainty in measurements, and third matrix associated with initial state.

Predicted state (vector) may correspond to an estimation of operational variables of the Li-ion battery system 101 calculated depending at least on measurements of the battery system 101 from e.g. sensors 107, previously modelled operational variables (obtained by e.g. prediction module 104 at previous iteration) once corrected (by e.g. correction module 105 at previous iteration), etc. Estimation of the corrected state (vector) may be defined iteratively (within iterative loop in whole method) and may imply an update rate suitable for properly receiving aforementioned inputs and calculating a difference or divergence between operational condition denoted by predicted state and operational condition denoted by measurements. Once determined such a divergence, correction module 105 may correct, based on e.g. Kalman filter, predicted state to generate present corrected state as a compensation or balancing between both inputs: predicted state and measurements. This manner, potential imperfections (or misalignments) in operational condition denoted by predicted state, and possible imperfections in operational condition denoted by measurements may be compensated or balanced to each other and, therefore, an improved (corrected) predicted state may be obtained. Examples of modelled internal variables forming the state of the battery system 101 or derivable therefrom may include, e.g., lithium concentration in electrodes (solid-phase), lithium concentration in electrolyte (liquid-phase), liquid-phase potential, solid-phase potential, intercalation fluxes, difference of potential between liquid phase and solid-phase, etc.

For example, predicted state correction performed by, e.g., correction module 105 may include correction between temperature and voltage (internal variables) within or derivable from predicted state (from e.g. prediction module 104) and temperature and voltage within measurement data from sensors 107. Extended Kalman filter, applied by correction module 105 in some examples, may include linear equality constraints which may force or ensure that results of correction module 105 are physically consistent. One example of said constraints may be based on, e.g., imposing total conservation of lithium concentration. Equality constraints may guarantee that present corrected state outputted by correction module 105 is consistent with a postulate according to which total quantity of lithium is conserved within the cell.

Extended Kalman filter may also consider inequality constraints, which may prevent from negative concentrations, or concentrations greater than a predetermined maximum concentration. Experiments have revealed that considering such inequality constraints may avoid obtaining results that are admissible by the extended Kalman filter but do not have physical meaning, i.e. are pure mathematical artefacts. In other words, inequality constraints may allow calculating constrained outputs in such a way that negative values (of e.g. concentrations) and values greater than maximum admissible concentrations (which may imply non-physically admissible values) are avoided.

Linear inequality constraints to be satisfied by the filter may be, e.g., formulated as follows:

$$G ( k ) x ( k ) \leq h ( k ) \qquad Formula 29$$

wherein k may be a natural number representing a time step, G(k) may be a matrix defining a linear constraint, and h(k) may correspond to right-hand side of the equation which may define a linear constraint. Linear inequality constraints may be included in extended Kalman filter to avoid bringing the model to an unfeasible state (e.g., with negative concentrations).

In present section about examples of correction module 105, particular manners of and fundamentals for correcting predicted state based on, e.g. Kalman filter or similar, have been provided. However, the skilled person should appreciate that other manners of doing so may be similarly practicable and/or implementable. No deep (known) details about correcting predicted state have been provided in order not to unnecessarily obscure the present description or developments, from which skilled people should be able to implement examples of first systems 100 according to present disclosure.

### Examples of Control Module 106 in First Systems 100

Control module 106 may be configured to receive present corrected state of the Li-ion battery system 101 (from e.g. correction module 105) and present current demanded (from e.g. prediction module 104 or directly from Li-ion battery system 101). Control module 106 may be further configured to output control signals for instructing the Li-ion battery system 101 to operate under desired or acceptable operational conditions such as, e.g., safe conditions. Such control signals may be determined by evaluating whether present current demanded (to the Li-ion battery system 101) is acceptable or unacceptable depending on present corrected state (of the Li-ion battery system 101). If present current demanded is determined acceptable, present current demanded may be preserved (e.g. multiplied by correction factor equal to 1) and control signals may be generated accordingly. Otherwise, if present current demanded is determined unacceptable, present current demanded may be downwardly corrected (e.g. multiplied by correction factor between 0 and 1) and control signals may be generated according to said correction.

Correction to be applied to present current demanded may be determined by, e.g., performing an optimization method to either minimize a correction/adjustment function or maximize a multiplier-factor (or correction factor) function to be applied to the present current demanded. This correction/adjustment function or multiplier-factor (or correction factor) function may depend on the present corrected state, in particular, on operational data included in or derivable from the present corrected state. Optimization method may be restricted to one or more constraints that may correspond to operational limits of the Li-ion battery system that may be or may have been pre-defined to guarantee safety and/or reliability and/or efficient operation of the Li-ion battery system 101.

If optimization method outputs minimum correction substantially equal to null or zero or, in other examples, maximum multiplier factor substantially equal to 1, present current demanded may be preserved. Otherwise, if minimum correction is different to null or zero or maximum multiplier factor is less than 1, present current demanded may be corrected based on minimum correction or maximum multiplier outputted by the optimization method. Correction function minimization and multiplier-factor (or correction factor) function maximization may be performed based on same or similar principles and assumptions. Conceptually, objectives of correction function minimization and multiplier-factor (or correction factor) function maximization may be perceived as different versions of same objective, i.e. both approaches perform same function or achieve same objective in different manners or from different perspectives.

Determining of correction (or multiplier factor) to be applied to present current demanded may further include performing a low-pass filter between present current demanded and previous corrected current demanded. Once the present current demanded has been corrected or preserved accordingly, the Li-ion battery system may be controlled based on control signals configured to instruct the Li-ion battery system 101 to supply electricity according to resulting present corrected current demanded. This manner, it may be guaranteed that the battery system 101 supplies maximum demanded current without exceeding capacity of the battery system 101 according to its present corrected state. Current constraints may limit current to be lower than a predefined current threshold, which may imply that current supplied by the battery system 101 may be less than current demanded at certain iterations. Capacity or operational limits of the battery system 101 regarding voltage, current, state of charge and temperature may be defined by manufacturer of the battery system 101, and those related to other variables such as, e.g., degradation concentrations and/or overpotentials, may be determined e.g. empirically.

Optimization method or process may also consider constraints on maximum and minimum voltage of the battery system 101. Voltage may be constrained to predefined range. Optimization method may further consider constraints aimed at keeping side reaction overpotential above certain range to avoid formation of, e.g., lithium plating. Minimum threshold for side reaction overpotential may be used to avoid formation of lithium plating, thereby keeping the side reaction overpotential greater than 0.01 V (10 mV).

Other constraints to be considered by optimization method may refer to temperature of the battery system 101, state of charge (SoC) of the battery system 101, concentration in liquid and/or solid phase to avoid electrolyte depletion, etc.

In present section about examples of control module 106, particular manners of and fundamentals for correcting current demanded and generating control signals accordingly have been provided. However, the skilled person should appreciate that other manners of doing so may be similarly practicable and/or implementable. No deep (known) details about correcting current demanded and generating control signals accordingly have been provided in order not to unnecessarily obscure the present description and development, from which skilled people should be able to implement examples of first systems 100 according to present disclosure.

### Examples of Saving Module (not Shown in Figures) in First Systems 100

Saving module may be configured to save or keep or register any data used or produced by first methods (performed by first systems 100) to be used in next iteration(s) of first methods. For example, such a saving functionality (performed by saving module) may include saving present corrected state and present corrected current demanded to be used as previous corrected state and previous corrected current demanded, respectively, in subsequent iteration of the iterative loop with in first methods.

Although saving module is not shown in Figures, it may be a separate module expressly configured to receive data (e.g., present corrected state, present corrected current demanded, etc.) to be used in next iteration(s) and to save said received data suitably. In alternative implementations, saving module may be included in or may be a sub-module of any of the other modules 104-106 that may see or know or have access to data to be saved. For example, saving module 106 may be included in control module 106. Any known storing device(s) and technique(s) may be used to implement such a storing functionality.

### Examples of First Methods Performable by First Systems 100

FIG. 2 is a flow chart schematically illustrating first methods of controlling a Li-ion battery system, according to examples. Since such first methods are performable by first systems according to FIG. 1, number references from said FIG. 1 may be reused in following description of FIG. 2.

First methods (of controlling a Li-ion battery system 101) according to FIG. 2 may be initiated (at e.g. method-block 200) upon detection of a starting condition such as e.g. a user request for starting the method, detection of activation or turn-on of the Li-ion battery system 101, etc.

First methods (of controlling a Li-ion battery system 101) according to FIG. 2 may further include obtaining (at e.g. method-block 201), based on a porous electrode model including degradation, and on the configuration specifications of the Li-ion battery system 101, a reduced order model of the Li-ion battery system 101 with a plurality of versions. Since this functionality of obtaining reduced order model (implemented at e.g. method-block 201) is performable by a module such as model module 102 of first systems 100, functional details and considerations previously explained with respect to said module 102 may be similarly attributed to this method-block 201.

First methods (of controlling a Li-ion battery system 101) according to FIG. 2 may still further include performing an iterative loop 202-206 which may start (at e.g. method-block 202) by determining a predicted state of the Li-ion battery system 101 by selecting a version of the reduced order model (from e.g. model module 102) corresponding to a previous corrected state of the Li-ion battery system 101 (from e.g. control module 106 at present iteration, and generated at previous iteration by e.g. correction module 105), and by calculating the predicted state based on the selected version of the reduced order model depending on the previous corrected state, a previous corrected current demanded to the Li-ion battery system 101 (from e.g. control module 106 at present iteration, and generated at previous iteration by e.g. control module 106), and a present current demanded (or current presently demanded or current demanded at present iteration) to the Li-ion battery system 101 (from e.g. Li-ion battery system 101 itself). Since this functionality of determining predicted state (implemented at e.g. method-block 202) is performable by a module such as prediction module 104 of first systems 100, functional details and considerations previously explained with respect to said module 104 may be similarly attributed to this method-block 202.

First methods (of controlling a Li-ion battery system 101) according to FIG. 2 may yet further include within iterative loop 202-206 determining (at e.g. method-block 203) a present corrected state of the Li-ion battery system 101 by applying a Kalman filter depending on the predicted state (from e.g. prediction module 104) and battery measurements (from e.g. sensors 107 arranged or installed in the Li-ion battery system 101). Since this functionality of determining present corrected state (implemented at e.g. method-block 203) is performable by a module such as correction module 105 of first systems 100, functional details and considerations previously explained with respect to said module 105 may be similarly attributed to this method-block 203.

First methods (of controlling a Li-ion battery system 101) according to FIG. 2 may furthermore include within iterative loop 202-206 controlling (at e.g. method-block 204) the Li-ion battery system 101 based on a present corrected current demanded resulting from correcting or preserving (at e.g. control module 106) the present current demanded (from e.g. prediction module 104 or Li-ion battery system 101) depending on the present corrected state (from e.g. correction module 105). Since this functionality of controlling Li-ion battery system 101 (implemented at e.g. method-block 204) is performable by a module such as control module 106 of first systems 100, functional details and considerations previously explained with respect to said module 106 may be similarly attributed to this method-block 204.

First methods (of controlling a Li-ion battery system 101) according to FIG. 2 may furthermore include within iterative loop 202-206 keeping or saving (at e.g. method-block 205) present corrected state (from e.g. correction module 105) and present corrected current demanded (from e.g. control module 106) to be used as previous corrected state and previous corrected current demanded, respectively, in subsequent iteration of the iterative loop 202-206. As described in other parts of the disclosure, this functionality of saving present corrected state and present corrected current demanded may be implemented by saving module which may be included in any of other modules 104-106 within iterative module 103 knowing or having access to present corrected state and present corrected current demanded. Accordingly, functional details and considerations previously explained with respect to saving module (not shown in FIG. 1) may be similarly attributed to this method-block 205.

First methods (of controlling a Li-ion battery system 101) according to FIG. 2 may yet furthermore include verifying (e.g. at decision block 206) whether an ending condition is satisfied. In case of positive or true result (Yes) of said verification, the method may be terminated by transitioning to e.g. ending block 207. Otherwise (No), the method may initiate a new iteration of the iterative loop 202-206 by transitioning back to e.g. block 202. The ending condition may be determined by detecting e.g. a user request for ending the method, deactivation or turn-off of the Li-ion battery system 101, etc.

### Examples of Second Systems 300 and Overview Thereof

Second systems 300 according to FIG. 3 may include a model module 302, a degradation module 308 and an iterative module 303. Such an iterative module 303 may include an estimation module 309, a prediction module 304, a correction module 305, a control module 306, and a saving module (not shown in Figure). Saving module may be configured to save working data determined in present iteration to be used in subsequent iteration, so saving module may be included in any one of the modules 304-306 that may see or know or have access to said working data. Sensors 307 may be arranged in/on the Li-ion battery system 301 to sense operational parameters of the Li-ion battery system 301 during operation. Sensors 307 may provide measurement values of the Li-ion battery system 301 during operation.

Modules 304-306 and 309 within iterative module 303 of second systems 300 may cooperate to implement an iterative process for controlling battery system 101. In this process, model module 302 may produce reduced order model without degradation having a plurality of versions, and degradation module 308 may produce degradation model just once at the beginning of the method, in off-line building approach as described in other parts of the disclosure. Alternatively, model module 302 may produce corresponding version of the reduced order model without degradation and degradation module 308 may produce degradation model at each iteration of the method, in on-line building approach as described in other parts of the disclosure. In the particular examples illustrated, second systems 300 belong to off-line building approach, since model module 302 obtains reduced order model with versions and degradation module 308 obtains degradation model before iterative loop implemented by iterative module 303.

Once degradation model is available (from e.g. degradation module 308), estimation module 309 may determine estimated degradation (for example, in terms of average anode porosity) of the Li-ion battery system 301 based on degradation model and previous corrected state of the Li-ion battery system 301. At first iteration, previous corrected state may be a predefined zero state simply because there is no previous iteration at which previous corrected state has been calculated. Degradation model may include a predefined initial degradation model corresponding to said previous corrected state predefined to zero, that is configured to estimate initial degradation at start of operation of the battery 301. This predefined initial degradation model may have been predetermined empirically.

Once estimated degradation is available (from e.g. estimation module 309), prediction module 304 may determine predicted state of the Li-ion battery system 101 in similar manner as explained with respect to prediction module 104 of first systems 100. A difference between prediction modules 104 and 304 resides in that, in second systems 300, reduced order model is without degradation and degradation-related data comes from estimation module 309 instead from prediction module 304. Prediction module 304 may thus select corresponding version of the reduced order model without degradation depending on previous corrected state (predefined zero state at first iteration) and estimated degradation (initial degradation at first iteration). Then, the selected version of the reduced order model without degradation may be computed depending on the previous corrected state, a previous corrected current demanded to the Li-ion battery system (also from previous iteration of the iterative loop), and a present current demanded to the Li-ion battery system 301.

Once predicted state is available, correction module 305 may generate present corrected state in same or similar manner as described with respect to correction module 105 in first systems 100, and control module 306 may generate control signals in same or similar manner as described with respect to control module 106 in first systems 100. FIG. 3 shows certain data flows providing data that may not be needed by receiving module but, in this case, said receiving module may simply act as a bridge to cause provided data to reach some other module. For example, previous corrected current demanded is shown passing from control module 306 to estimation module 309, in spite of previous corrected current demanded may not be needed or used by estimation module 309. Therefore, in this case, estimation module 309 acts as a bridge to cause prediction module 304 to receive the previous corrected current demanded. It will be apparent to skilled person when a given module performs such a bridge function in the context of and according to present disclosure, so no further details in this respect are provided. Such bridge actuations may be present in any of the first and second systems/methods of controlling Li-ion battery system 301.

### Examples of Model Module 302 in Second Systems 300

Model module 302 in second systems 300 may be similarly (not equally in any case) implemented or configured as model module 102 in first systems 100. A main difference between model modules 102 and 302 resides in that model module 302 determines versioned reduced order model (e.g. reduced order SSM) with no modelling of degradation. Such a functionality of determining versioned reduced order model without degradation may include adapting and reducing porous electrode model without degradation depending on configuration specifications of the Li-ion battery system 101 and, in some examples, predefined operational states or conditions that are known to be experienced by the Li-ion battery system 101 during operation. Such predefined operational states or conditions may include, e.g., cell temperature, state-of-charge, and average anode porosity.

As described with respect to model module 102 in first systems 100, any known porous electrode model (without degradation in second systems 300) may be used as starting point to implement functionality of determining versioned reduced order model (e.g. reduced order SSM) without degradation. Same or similar principles and techniques as those commented regarding model module 102 may thus be used in model modules 302 to accordingly adapt and reduce porous electrode model without degradation. The fact that no degradation-related parameters nor calculations are considered in second systems 300 to generate versioned reduced order model (without degradation) does not invalidate main principles and techniques described to generate reduced order model with degradation in first systems 100.

### Examples of Degradation Module 308 in Second Systems 300

Degradation module 308 may be configured to determine degradation model, i.e. a model of how Li-ion battery system 301 degrades over operation time, which may depend on configuration specifications of the Li-ion battery system 301 and, in some examples, on predefined operational states or conditions that are known to be experienced by the Li-ion battery system 301 during operation. Such a functionality of generating degradation model may start from any known electrochemical degradation model and may be based on adapting said electrochemical degradation model depending on type of battery system 301 to be controlled (i.e. configuration specifications, predefined operational states or conditions, etc.).

Aforementioned “starting” electrochemical degradation model may, e.g., include or define an electrochemical aging model that models solid electrolyte interface (SEI) formation, lithium plating, lithium stripping, etc. along with degradation effects thereof. Electrochemical aging model may model lithium plating at least when a difference of liquid phase and solid phase potentials at anode becomes negative with respect to lithium plating equilibrium potential. Electrochemical aging model may (additionally or alternatively) model lithium stripping as potential subsequent effect while discharging while lithium is already plated, at least partially.

Degradation module 308 may generate degradation model based on one or more of following parameters: solid-electrolyte interface equilibrium potential Uₛₑᵢ, solid-electrolyte interface exchange current density i_{0,sei}, solid-electrolyte interface charge-transfer coefficient αₛₑᵢ, solid-electrolyte interface density ρₛₑᵢ, solid-electrolyte interface molar mass Mₛₑᵢ, ionic film conductivity κ_{film}, electronic film conductivity σ_{film}, initial film thickness δ_{0,film}, lithium plating/stripping equilibrium potential Uₗₚₗ/Uₗₛₜ, lithium plating/stripping exchange current density i_{0,lpl}/i_{0,lst}, lithium plating/stripping charge-transfer coefficient αₗₚₗ/αₗₛₜ, lithium density ρ_{Li}, lithium molar mass M_{Li}, ratio of reversibly plated lithium ξ, etc.

Degradation model may be generated (additionally or alternatively) including modelling of degradation mechanisms locatable in/on particle/film surface. Such degradation mechanisms may refer to solid electrolyte interface (SEI) formation, lithium plating, lithium stripping, etc. and may also consider, in some examples, resistances due to ion and electron flux generated or consumed by said mechanisms.

Degradation module 308 may further be configured to store the generated degradation model, such that estimation model 309 may determine therefrom an estimated degradation depending on previous corrected state (from, e.g., control module 306 or correction module 305). Such a degradation estimation may be performed by coupling the generated degradation model with state-data derived from reduced order model without degradation (e.g. previous corrected state).

Aging model of lithium deposition or plating at the anode during charge may be characterized by a distributed algebraic equation which, in some examples, may be constrained by associated overpotential(s) defined in Formula 22 to be non-positive. The distributed algebraic equation may come from adapting well-known Tafel equation to model lithium deposition or plating.

Similarly, aging model of lithium dissolution or stripping at anode during discharge may be characterized by a distributed algebraic equation based on or coming from adapting well-known Tafel equation to model lithium stripping side reaction and/or a two-parameter sigmoid-like function that may depend on a ratio of reversibly plated lithium ξ, charge quantities of plated lithium qₗₚₗ and stripped lithium qₗₛₜ, etc.

Both mechanisms plating and stripping may be modelled as if they were the same mechanism by a semi-reversible reaction. This may be implemented by using a Butler-Volmer equation similar to the one used in intercalation. Plating (or deposition) and stripping (or dissolution) may be distinguished from each other through respective two irreversible reactions, one for each of said phenomena. This may be done by using two Tafel equations (one in charging for plating and one in discharging for stripping). The reason why sigmoid-like function may be used is because lithium that has not been previously deposited cannot be dissolved.

Solid electrolyte interface (SEI) formation may be modelled as a semi-reversible reaction by using corresponding Butler-Volmer equation or, alternatively, as an irreversible reaction by using a Tafel type equation such as in following formula 32.

Degradation module 308 may generate degradation model (additionally or alternatively) including modelling of degradation rates based on computing a distributed algebraic equation depending on degradation overpotentials (e.g. those modelled according to formulas 21, 22, 23) in following manner:

$${j}_{l p l} = \{ \begin{matrix}2 {a}_{s}^{n} {i}_{0 , lpl} sinh ( \frac{{α}_{lpl} F}{{RT}^{n}} {η}_{lpl} ) & if {η}_{lpl} \leq 0 \\ 0 & if {η}_{lpl} > 0\end{matrix} \qquad formula 30$$

$${j}_{lst} = \{ \begin{matrix}2 {a}_{s}^{n} {i}_{0 , lst} sinh ( \frac{{α}_{lst} F}{{RT}^{n}} {η}_{lst} ) σ ( - ξ {q}_{lpl} - {q}_{lst} ) & if {η}_{lst} \geq 0 \\ 0 & if {η}_{lst} < 0\end{matrix} \qquad formula 31$$

$${j}_{s e i} = - {a}_{s}^{n} {i}_{0 , sei} sinh ( \frac{{α}_{s e i} F}{R {T}^{n}} {η}_{s e i} ) \qquad formula 32$$

Parameters, variables, constants, etc. intervening in said formulas 30-32 are well known to skilled people. However, all or most of them have been defined previously.

Degradation module 308 may generate degradation model (additionally or alternatively) including modelling of degradation film growth at e.g. negative electrode, from ordinary differential equation(s) and degradation rate(s) (calculated according to e.g. formulas 30-32), in following manner:

$$- \frac{\partial {δ}_{f i l m}^{n}}{\partial t} = \frac{{M}_{s e i}}{F {ρ}_{s e i}} \frac{1}{{a}_{s}^{n}} {j}_{s e i} + \frac{{M}_{L i}}{F {ρ}_{L i}} \frac{1}{{a}_{s}^{n}} ( {j}_{l p l} + {j}_{lst} ) \qquad formula 33$$

Parameters, variables, constants, etc. intervening in said formula 33 are well known to skilled people. However, all or most of them have been defined previously.

Degradation module 308 may generate degradation model (additionally or alternatively) including modelling of porosity evolution at negative electrode depending on e.g. degradation film, in following manner:

$$- \frac{\partial {ϵ}_{e}^{n}}{\partial t} = {a}_{s}^{n} \frac{\partial {δ}_{f i l m}^{n}}{\partial t} \qquad formula 34$$

Parameters, variables, constants, etc. intervening in said formula 34 are well known to skilled people. However, all or most of them have been defined previously.

Degradation module 308 may generate degradation model (additionally or alternatively) including an electrochemical aging model of solid electrolyte interface formation, wherein flux at solid-electrolyte interface in anode may be characterized by a distributed algebraic equation including solid-electrolyte interface overpotential. An amount of solid-electrolyte interface charge at anode may be characterized by a distributed ordinary differential equation. Overpotential at solid electrolyte interface may have a resistive term that may involve its associated flux and i.e., increase cell resistance which may cause a loss of cell capacity.

Lithium plating and stripping reactions may be modelled (at or by degradation model) with constraints that may be strongly dependent on charge/discharge behaviour as opposed to solid-electrolyte interface which may grow not only in charge, but also in discharge and relaxation as far as anode is lithiated enough. Relaxation may occur when battery system is disconnected to decrease cell polarization and to substantially reach equilibrium. Aging model of solid electrolyte may reflect such difference with respect to other degradation factors by using a set of equations both in charge and discharge. In some examples, aging model may use a single set of equations both in charge and discharge.

In present section about degradation module 308, particular manners of and fundamentals for obtaining degradation model have been described, but skilled people will appreciate that other manners of doing so may be similarly practicable and/or implementable. No deep (known) details about modelling degradation have been provided in order not to unnecessarily obscure the present description and developments, from which skilled people should be able to implement examples of second systems 300 according to present disclosure.

### Examples of Estimation Module 309 in Second Systems 300

Estimation module 309 may be configured to receive or obtain degradation model (from e.g. degradation module 308) and previous corrected state (from e.g. control module 306). Estimation module 309 may be further configured to estimate degradation data depending on degradation model and previous corrected state. As described before, previous corrected state may be a predefined zero state at first iteration. Estimation module 309 may be further configured to send or provide estimated degradation, previous corrected state, previous corrected current demanded, etc. to e.g. prediction module 304. Said data provision may be performed, for some of the provided data, by estimation module 309 acting as a bridge in the sense explained in other parts of the disclosure. Such a bridge functionality may be performed by other modules within iterative loop.

Estimation module 309 may estimate degradation data including, e.g., porosity at different points in the battery system 101 depending on degradation model (from e.g. degradation module 308) and previous corrected state of the battery system 101. In particular, porosity at different positions in the battery system 101 may be estimated from degradation rate(s) modelled by degradation model once coupled with previous corrected state. Said coupling may be performed by computing degradation model so as to calculate porosity as a function of the previous corrected state. For example, with the previous corrected state, degradation overpotentials may be obtained according to e.g. Formulas 21-23, and with degradation overpotentials, flows may be obtained according to e.g. Formulas 30-32, and finally porosity may be obtained by joining Formulas 33 and 34.

### Examples of Prediction Module 304 in Second Systems 300

Prediction module 304 in second systems 300 may be similarly (not equally in any case) implemented or configured as prediction module 104 in first systems 100. A main difference between prediction modules 104 and 304 resides in that prediction module 304 uses versioned reduced order model (from e.g. model module 302) with no modelling of degradation. Accordingly, prediction module 304 uses estimated degradation determined (by e.g. estimation module 309) based on degradation model (from e.g. degradation module 308) independently or separately from versioned reduced order model. Functional details and considerations previously explained with respect to prediction module 104 may, hence, be similarly attributed to prediction module 304, excepting those aspects associated to modelling of degradation and application thereof in determination of predicted state (i.e. prediction functionality).

In case of prediction functionality includes performing some calculation using or depending on degradation-related data, said data may be exclusively obtained from estimated degradation data outputted by e.g. estimation module 309. For instance, in selecting version of the reduced order model (without degradation) to be used for determining predicted state, said version may be selected depending on previous corrected state (determined by e.g. correction module 305 at previous iteration) and estimated degradation (from e.g. estimation module 309). When versions of the reduced order model are represented or implemented by corresponding SSM-matrices, SSM-matrices may be determinable at least partially depending on data representing or being derivable from estimated or modelled degradation, said degradation-related data not coming from reduced order model, but from degradation modelling through suitable degradation model (outputted by e.g. degradation module 308). In examples where blending process is performed at least partially based on average porosity (which is degradation-related data), prediction functionality (performed by e.g. prediction module 304) may obtain said degradation-related data exclusively from degradation modelling or estimation (performed by e.g. estimation module 309 in cooperation with degradation module 308).

### Examples of Correction Module 305 in Second Systems 300

Correction module 305 in second systems 300 may be equally or similarly implemented or configured as correction module 105 in first systems 100. Therefore, functional details and considerations previously explained with respect to correction module 105 may be similarly attributed to correction module 305.

### Examples of Control Module 306 in Second Systems 300

Control module 306 in second systems 300 may be equally or similarly implemented or configured as control module 106 in first systems 100. Therefore, functional details and considerations previously explained with respect to control module 106 may be similarly attributed to control module 306.

### Examples of Saving Module (not Shown in Figures) in Second Systems 300

Saving module (not shown) in second systems 300 may be equally or similarly implemented or configured as saving module (not shown) in first systems 100. Therefore, functional details and considerations previously explained with respect to saving module in first systems 100 may be similarly attributed to saving module in second systems 300.

### Examples of Second Methods Performable by Second Systems 300

FIG. 4 is a flow chart schematically illustrating second methods of controlling a Li-ion battery system, according to examples. Since such second methods according to FIG. 4 are performable by second systems 300 according to FIG. 3, number references from said FIG. 3 may be reused in following description of FIG. 4.

Second methods (of controlling a Li-ion battery system 301) according to FIG. 4 may be initiated (at e.g. method-block 400) upon detection of a starting condition such as e.g. a user request for starting the method, detection of activation or turn-on of the Li-ion battery system 301, etc.

Second methods (of controlling a Li-ion battery system 301) according to FIG. 4 may further include obtaining (at e.g. method-block 401) a versioned reduced order model without degradation based on a porous electrode model without degradation and on configuration specifications of the Li-ion battery system 301. Since this functionality of obtaining versioned reduced order model (implemented at e.g. method-block 401) is performable by a module such as model module 302 of second systems 300, functional details and considerations previously explained with respect to said module 302 may be similarly attributed to this method-block 401.

Second methods (of controlling a Li-ion battery system 301) according to FIG. 4 may still further include obtaining (at e.g. method-block 402) a degradation model based on an electrochemical degradation model and on configuration specifications of the Li-ion battery system 301. Since this functionality of obtaining degradation model (implemented at e.g. method-block 402) is performable by a module such as degradation module 308 of second systems 300, functional details and considerations previously explained with respect to said module 308 may be similarly attributed to this method-block 402.

Second methods (of controlling a Li-ion battery system 301) according to FIG. 4 may yet further include performing an iterative loop 403-408 which may start (at e.g. method-block 403) by determining an estimated degradation of the Li-ion battery system 301 based on the degradation model (from e.g. degradation module 308), and on a previous corrected state of the Li-ion battery system (from e.g. control module 306 at present iteration, and generated at previous iteration by e.g. correction module 305). Since this functionality of determining estimated degradation (implemented at e.g. method-block 403) is performable by a module such as estimation module 309 of second systems 300, functional details and considerations previously explained with respect to said module 309 may be similarly attributed to this method-block 403.

Second methods (of controlling a Li-ion battery system 301) according to FIG. 4 may furthermore include within iterative loop 403-408 determining (at e.g. method-block 404) a predicted state of the Li-ion battery system 301 by selecting a version of the reduced order model without degradation (from e.g. model module 302) corresponding to previous corrected state (from e.g. estimation module 309 at present iteration, and generated at previous iteration by e.g. correction module 305) and estimated degradation (from e.g. estimation module 309), and by calculating the predicted state based on the selected version of the reduced order model without degradation depending on previous corrected state, previous corrected current demanded to the Li-ion battery system 301 (from e.g. estimation module 309 at present iteration, and generated at previous iteration by e.g. control module 306), and on present current demanded to the Li-ion battery system 301 (from e.g. Li-ion battery system 301 itself). Since this functionality of obtaining predicted state (implemented at e.g. method-block 404) is performable by a module such as prediction module 304 of second systems 300, functional details and considerations previously explained with respect to said module 304 may be similarly attributed to this method-block 404.

Second methods (of controlling a Li-ion battery system 301) according to FIG. 4 may still furthermore include within iterative loop 403-408 determining (at e.g. method-block 405) a present corrected state of the Li-ion battery system 301 by applying a Kalman filter depending on predicted state (from e.g. prediction module 304) and battery measurements (from e.g. sensors 307 arranged or installed in the Li-ion battery system 301). Since this functionality of determining present corrected state (implemented at e.g. method-block 405) is performable by a module such as correction module 305 of second systems 300, functional details and considerations previously explained with respect to said module 305 may be similarly attributed to this method-block 405.

Second methods (of controlling a Li-ion battery system 301) according to FIG. 4 may also include within iterative loop 403-408 controlling (at e.g. method-block 406) the Li-ion battery system 301 depending on present corrected current demanded resulting from correcting (or preserving) (at e.g. control module 306) the present current demanded (from e.g. prediction module 304 or Li-ion battery system 301) depending on the present corrected state (from e.g. correction module 305). Since this functionality of controlling Li-ion battery system 301 (implemented at e.g. method-block 406) is performable by a module such as control module 306 of second systems 300, functional details and considerations previously explained with respect to said module 306 may be similarly attributed to this method-block 406.

Second methods (of controlling a Li-ion battery system 301) according to FIG. 4 may also include within iterative loop 403-408 keeping or saving (at e.g. method-block 407) present corrected state (from e.g. correction module 305) and present corrected current demanded (from e.g. control module 306) to be used as previous corrected state and previous corrected current demanded, respectively, in subsequent iteration of the iterative loop 403-408. As described in other parts of the disclosure, this functionality of saving present corrected state and present corrected current demanded may be implemented by saving module which may be included in any of other modules 304, 305, 306, 309 within iterative module 303 knowing or having access to present corrected state and present corrected current demanded. Accordingly, functional details and considerations previously explained with respect to saving module (not shown in FIG. 3) may be similarly attributed to this method-block 407.

Second methods (of controlling a Li-ion battery system 301) according to FIG. 4 may still also include verifying (e.g. at decision block 408) whether an ending condition is satisfied. In case of positive or true result (Yes) of said verification, the method may be terminated by transitioning to e.g. ending block 409. Otherwise (No), the method may initiate a new iteration of the iterative loop 403-408 by transitioning back to e.g., block 403. The ending condition may be determined by detecting e.g. a user request for ending the method, deactivation or turn-off of the Li-ion battery system 301, etc.

Although only a number of examples have been disclosed herein, other alternatives, modifications, uses and/or equivalents thereof are possible. Furthermore, all possible combinations of the described examples are also covered. Thus, the scope of the present disclosure should not be limited by particular examples but should be determined only by a fair reading of the claims that follow.

1. A method of controlling operation of a Li-ion battery system having configuration specifications, the method comprising:
obtaining, based on a porous electrode model including degradation and on the configuration specifications, a reduced order model of the Li-ion battery system having a plurality of selectable versions;
performing an iterative loop with each iteration of the iterative loop including:
determining a predicted state of the Li-ion battery system by selecting a version of the reduced order model depending on a previous corrected state of the Li-ion battery system from previous iteration of the iterative loop, and by calculating the predicted state based on the selected version of the reduced order model depending on the previous corrected state, a previous corrected current demanded to the Li-ion battery system from previous iteration of the iterative loop, and a present current demanded to the Li-ion battery system;
determining a present corrected state of the Li-ion battery system by applying a Kalman filter depending on the predicted state and battery measurements from sensors arranged or installed in the Li-ion battery system;
controlling the Li-ion battery system based on a present corrected current demanded resulting from correcting the present current demanded depending on the present corrected state; and
keeping or saving the present corrected state and the present corrected current demanded to be used as the previous corrected state and the previous corrected current demanded, respectively, in subsequent iteration of the iterative loop.

2. (canceled)

3. A method of controlling operation of a Li-ion battery system according to claim 1, the obtaining of the reduced order model including:
determining transfer functions derived from partial differential equations defining the porous electrode model including degradation.

4. A method of controlling operation of a Li-ion battery system according to claim 3, at least some of the transfer functions being determined to model degradation rates at different locations of the Li-ion battery system.

5. A method of controlling operation of a Li-ion battery system according to claim 4, the different locations of the Li-ion battery system at which degradation rates are modelled including one or more or any combination of anode and cathode and separator between anode and cathode of the Li-ion battery system.

6. A method of controlling operation of a Li-ion battery system according to claim 4, the modelling of degradation rates by one or more of the transfer functions including
modelling degradation overpotentials due to one or more of lithium stripping or lithium plating or solid-electrolyte interface formation, or any combination thereof.

7. A method of controlling operation of a Li-ion battery system according to claim 6, the modelling of degradation overpotentials by one or more of the transfer functions including
modelling a solid phase potential at one or both anode and cathode, or a liquid phase potential at one or more or any combination of anode and cathode and separator of the Li-ion battery system, or any combination thereof.

8. A method of controlling operation of a Li-ion battery system according to claim 4, the modelling of degradation rates by one or more of the transfer functions including
modelling porosity evolution at one or both anode and cathode depending on the modelling of the degradation rates.

9. (canceled)

10. (canceled)

11. (canceled)

12. (canceled)

13. A method of controlling operation of a Li-ion battery system according to claim 1, the obtaining of the reduced order model including:
applying a discrete realization algorithm, DRA, to obtain the reduced order model as a reduced-order discrete-time state-space model, SSM, further depending on predefined operational states or conditions that are known to be experienced by the Li-ion battery system during operation.

14. (canceled)

15. (canceled)

16. A method of controlling operation of a Li-ion battery system according to claim 13, the reduced-order discrete-time SSM being defined by SSM-formulas and SSM-matrices intervening in said SSM-formulas; and
the determining of the predicted state of the Li-ion battery system including:
selecting SSM-matrices to solve the SSM-formulas depending on the previous corrected state; and
solving the SSM-formulas based on the selected SSM-matrices, on the previous corrected state of the Li-ion battery system, on the previous corrected current demanded, and on the present current demanded.

17. A method of controlling operation of a Li-ion battery system according to claim 16, the selecting of the SSM-matrices including performing a blending method depending on the previous corrected state of the Li-ion battery system, so as to select some SSM-matrices or others to solve the SSM-formulas,
the performing of the blending method to select some SSM-matrices or others including:
verifying whether there exist SSM-matrices corresponding to the previous corrected state, in which case said correspondent SSM-matrices are selected and, otherwise, an interpolation of neighbouring SSM-matrices is performed.

18. (canceled)

19. A method of controlling operation of a Li-ion battery system according to claim 17, the performing of the blending method to select some SSM-matrices or others being performed depending on an average cell temperature included in or derived from the previous corrected state, a state-of-charge or SoC included in or derived from the previous corrected state, and an average of anode porosity included in or derived from the previous corrected state.

20. (canceled)

21. (canceled)

22. (canceled)

23. (canceled)

24. (canceled)

25. (canceled)

26. (canceled)

27. (canceled)

28. (canceled)

29. A computer program including program instructions for causing a computing system to perform a method according to claim 1 of controlling operation of a Li-ion battery system.

30. (canceled)

31. (canceled)

32. (canceled)

33. A computing system including a memory and a processor, embodying instructions stored in the memory and executable by the processor, and the instructions including functionalities to execute a method according to claim 1 of controlling operation of a Li-ion battery system.

34. A method of controlling operation of a Li-ion battery system having configuration specifications, the method comprising:
obtaining, based on a porous electrode model without degradation and on the configuration specifications, a reduced order model without degradation of the Li-ion battery system having a plurality of selectable versions;
obtaining a degradation model based on an electrochemical degradation model and on the configuration specifications; and
performing an iterative loop with each iteration of the iterative loop including:
determining an estimated degradation of the Li-ion battery system based on the degradation model, and on a previous corrected state of the Li-ion battery system from previous iteration of the iterative loop;
determining a predicted state of the Li-ion battery system by selecting a version of the reduced order model without degradation depending on the previous corrected state and the estimated degradation, and by calculating the predicted state based on the selected version of the reduced order model without degradation depending on the previous corrected state, a previous corrected current demanded to the Li-ion battery system from previous iteration of the iterative loop, a present current demanded to the Li-ion battery system;
determining a present corrected state of the Li-ion battery system by applying a Kalman filter depending on the predicted state and battery measurements from sensors arranged or installed in the Li-ion battery system;
controlling the Li-ion battery system based on a present corrected current demanded resulting from correcting the present current demanded depending on the present corrected state; and
keeping or saving the present corrected state and the present corrected current demanded to be used as the previous corrected state and the previous corrected current demanded, respectively, in subsequent iteration of the iterative loop.

35. (canceled)

36. (canceled)

37. (canceled)

38. (canceled)

39. (canceled)

40. (canceled)

41. (canceled)

42. A method of controlling operation of a Li-ion battery system according to claim 34, the obtaining of the degradation model comprising determining the degradation model including modelling degradation rates at different locations of the Li-ion battery system, said different locations including one or more or any combination of anode and cathode and separator between anode and cathode of the Li-ion battery system.

43. (canceled)

44. A method of controlling operation of a Li-ion battery system according to claim 42, the modelling of degradation rates by the degradation model including
modelling degradation overpotentials due to one or more of lithium stripping or lithium plating or solid-electrolyte interface formation, or any combination thereof.

45. A method of controlling operation of a Li-ion battery system according to claim 44, the modelling of degradation overpotentials by the degradation model including
modelling a solid phase potential at one or both of anode and cathode, or a liquid phase potential at one or more of anode and cathode and separator of the Li-ion battery system, or any combination thereof.

46. A method of controlling operation of a Li-ion battery system according to claim 42, the modelling of degradation rates by the degradation model including
modelling porosity evolution at one or both of anode and cathode depending on the modelling of the degradation rates.

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. A computer program including program instructions for causing a computing system to perform a method according to claim 34 of controlling operation of a Li-ion battery system.

63. (canceled)

64. (canceled)

65. (canceled)

66. A computing system including a memory and a processor, embodying instructions stored in the memory and executable by the processor, and the instructions including functionalities to execute a method according to claim 34 of controlling operation of a Li-ion battery system.
